(19) United States
(12) Patent Application Publication
(10) Pub. No.: US 2016/0072077 A1
(43) Pub. Date: Mar. 10, 2016

(54) ORGANIC LIGHT EMITTING DIODE AND ORGANIC LIGHT EMITTING DISPLAY DEVICE INCLUDING THE SAME

(71) Applicant: SAMSUNG DISPLAY CO., LTD., Yongin-City (KR)

(72) Inventors: Naoyuki ITO, Seongnam-si (KR); Seul Ong KIM, Suwon-si (KR); Youn Sun KIM, Seoul (KR); Dong Woo SHIN, Seoul (KR); Jung Sub LEE, Bucheon-si (KR)

(21) Appl. No.: 14/800,165

(22) Filed: Jul. 15, 2015

(30) Foreign Application Priority Data
Sep. 4, 2014 (KR) 10-2014-0117616

(51) Int. Cl. H01L 51/00; C09K 11/02; H01L 27/32

(52) U.S. Cl. CPC H01L 51/0072; H01L 51/0081; H01L 27/3276; H01L 51/0058; C09K 11/025; H01L 51/0067; H01L 51/0071; H01L 51/0077; H01L 51/5096

(57) ABSTRACT

An organic light emitting element and an organic light emitting display, the organic light emitting element including a first compound represented by one of Chemical Formula 1-A to Chemical Formula 1-G, and a second compound represented by Chemical Formula 2:

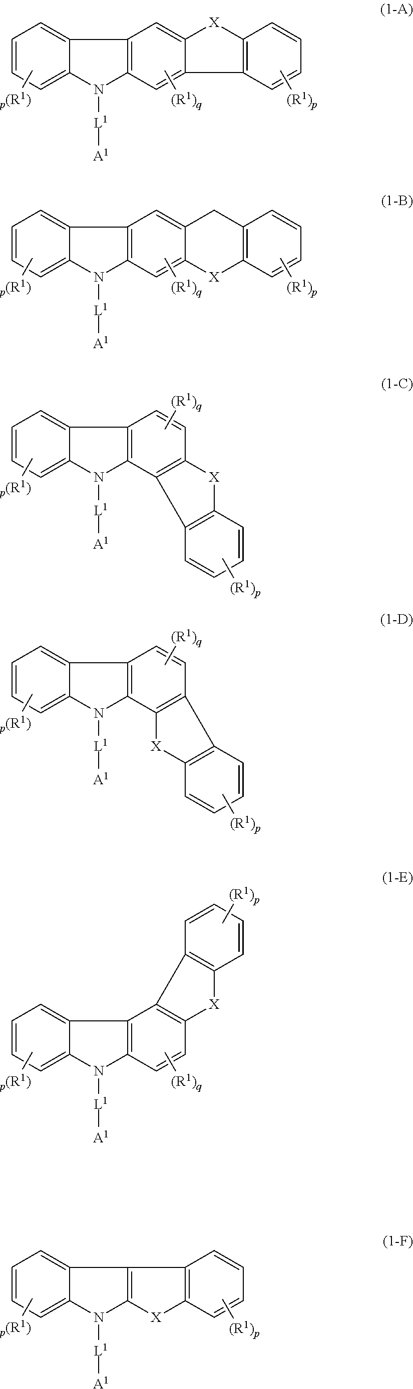

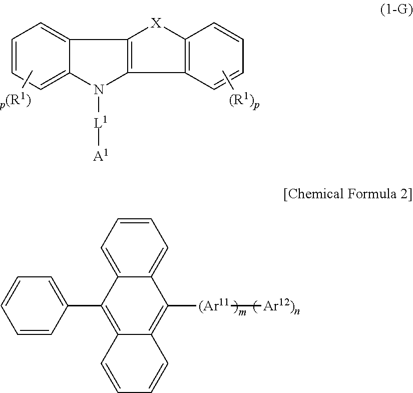

### CROSS-REFERENCE TO RELATED APPLICATION

Korean Patent Application No. 10-2014-0117616, filed on Sep. 4, 2014, in the Korean Intellectual Property Office, and entitled: “Organic Light Emitting Diode and Organic Light Emitting Display Device Including the Same,” is incorporated by reference herein in its entirety.

### BACKGROUND

1. Field

Embodiments relate to an organic light emitting element and an organic light emitting device including the same.

2. Description of the Related Art

Recently, lightness and flatness of a monitor, a television, or the like have been demanded, and a cathode ray tube (CRT) has been substituted with a liquid crystal display (LCD) according to the demand. However, the liquid crystal display, which is a light receiving element, requires a separate backlight, and has a limitation in response speed, viewing angle, and the like.

An organic light emitting device, which is a self-emitting display element may have advantages of a wide viewing angle, excellent contrast, and a fast response time, and has greatly attracted attention.

The organic light emitting device may include an organic light emitting element for light emission. The organic light emitting element may form excitons from combination of electrons injected from one electrode and holes injected from another electrode in an emission layer, and the excitons may emit energy such that light is emitted.

The above information disclosed in this Background section is only for enhancement of understanding of the background and therefore it may contain information that does not form the prior art that is already known in this country to a person of ordinary skill in the art.

### SUMMARY

Embodiments are directed to an organic light emitting element and an organic light emitting device including the same.

The embodiments may be realized by providing an organic light emitting element including a first compound represented by one of Chemical Formula 1-A to Chemical Formula 1-G, and a second compound represented by Chemical Formula 2:

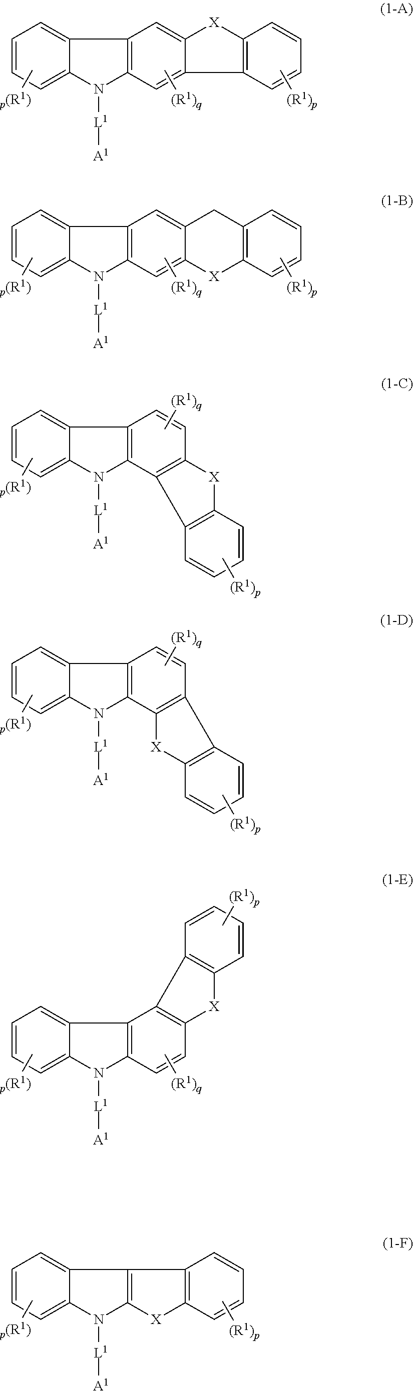

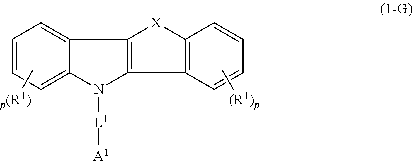

wherein, in Chemical Formula 1-A to Chemical Formula 1-G, A¹ is a substituted or unsubstituted C6 to C30 aromatic hydrocarbon group or a substituted or unsubstituted ring-type C6 to C30 condensed aromatic heterocyclic group, L¹ is a single bond, a substituted or unsubstituted C6 to C30 aromatic hydrocarbon group, a substituted or unsubstituted C6 to C30 condensed aromatic hydrocarbon group, a substituted or unsubstituted C2 to C30 aromatic heterocyclic group, or a substituted or unsubstituted C2 to C30 condensed aromatic heterocyclic group, X is S, O, N—R′, or C(R¹)₂, each R¹ is independently hydrogen, fluorine, a cyano group, a substituted or unsubstituted C1 to C20 alkyl group, a substituted or unsubstituted C1 to C20 alkoxy group, a substituted or unsubstituted C1 to C20 haloalkyl group, a substituted or unsubstituted C1 to C20 haloalkoxy group, a substituted or unsubstituted C1 to C10 alkylsilyl group, a substituted or unsubstituted C6 to C30 arylsilyl group, a substituted or unsubstituted C6 to C30 aromatic hydrocarbon group, a substituted or unsubstituted C6 to C30 condensed aromatic hydrocarbon group, a substituted or unsubstituted C2 to C30 aromatic heterocyclic group, or a substituted or unsubstituted C2 to C30 condensed aromatic heterocyclic group, p is an integer of 1 to 4, q is an integer of 1 to 2,

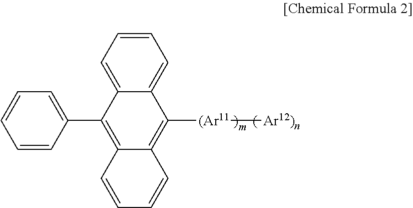

wherein, in Chemical Formula 2, each Ar¹¹ is independently a substituted or unsubstituted C5 to C30 arylene group or a substituted or unsubstituted C5 to C30 heteroarylene group, m is an integer of 0 to 3, such that when m is 0, Ar¹¹ is a single bond, each Ar¹² is independently a substituted or unsubstituted C5 to C30 aryl group or a substituted or unsubstituted C5 to C30 heteroaryl group, and n is an integer of 1 to 3.

The organic light emitting element may include an anode and a cathode that face each other; an emission layer between the anode and the cathode; a hole transfer layer between the anode and the emission layer; an electron transfer layer between the cathode and the emission layer; and a hole blocking layer between the electron transfer layer and the emission layer, the hole blocking layer may include the first compound, and the emission layer may include the second compound.

Ar¹¹ of the second compound may include a substituted or unsubstituted phenylene group or a substituted or unsubstituted naphthylene group.

The first compound may be represented by one of the following Chemical Formula 1-1 to Chemical Formula 1-7:

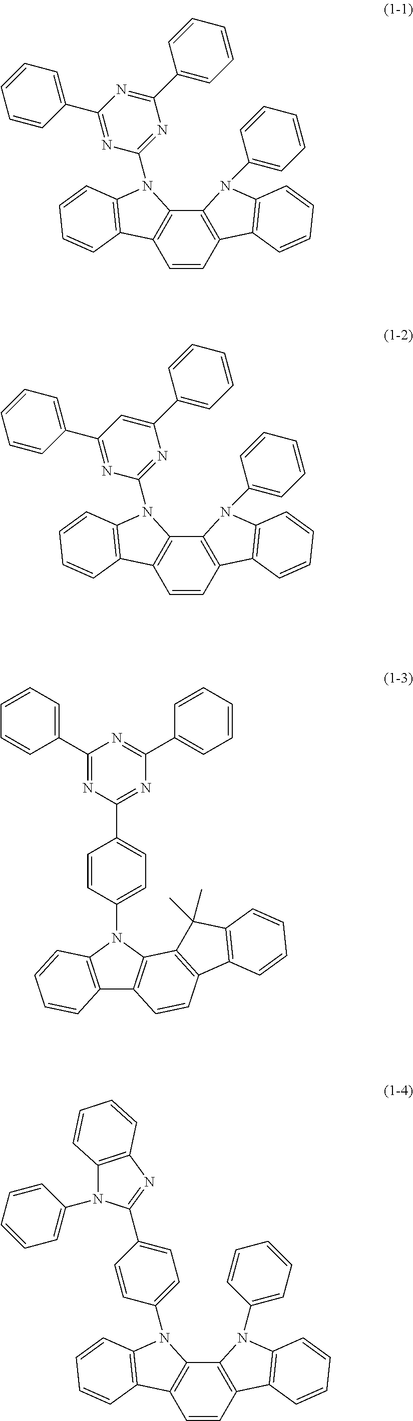 [SMILES: c1ccc(-c2nc(-c3ccccc3)nc(-n3c4ccccc4c4ccc5c6ccccc6n(-c6ccccc6)c5c43)n2)cc1 ; c1ccc(-c2cc(-c3ccccc3)nc(-n3c4ccccc4c4ccc5c6ccccc6n(-c6ccccc6)c5c43)n2)cc1 ; CC1(C)c2ccccc2-c2ccc3c4ccccc4n(-c4ccc(-c5nc(-c6ccccc6)nc(-c6ccccc6)n5)cc4)c3c21 ; c1ccc(-n2c(-c3ccc(-n4c5ccccc5c5ccc6c7ccccc7n(-c7ccccc7)c6c54)cc3)nc3ccccc32)cc1]

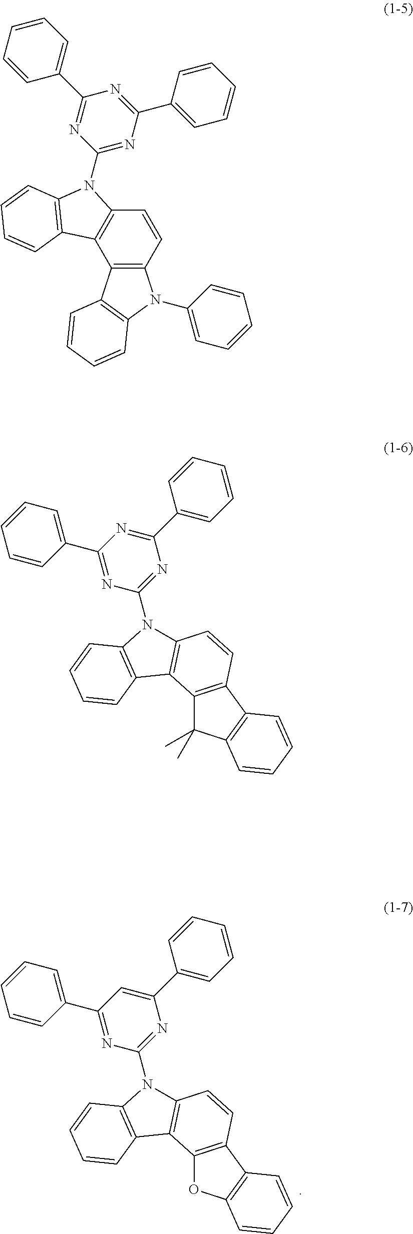 [SMILES: c1ccc(-c2nc(-c3ccccc3)nc(-n3c4ccccc4c4c5c6ccccc6n(-c6ccccc6)c5ccc43)n2)cc1 ; CC1(C)c2ccccc2-c2ccc3c(c21)c1ccccc1n3-c1nc(-c2ccccc2)nc(-c2ccccc2)n1 ; c1ccc(-c2cc(-c3ccccc3)nc(-n3c4ccccc4c4c5oc6ccccc6c5ccc43)n2)cc1 ; "."]

The second compound may be represented by one of the following Chemical Formula 2-1 to Chemical Formula 2-8:

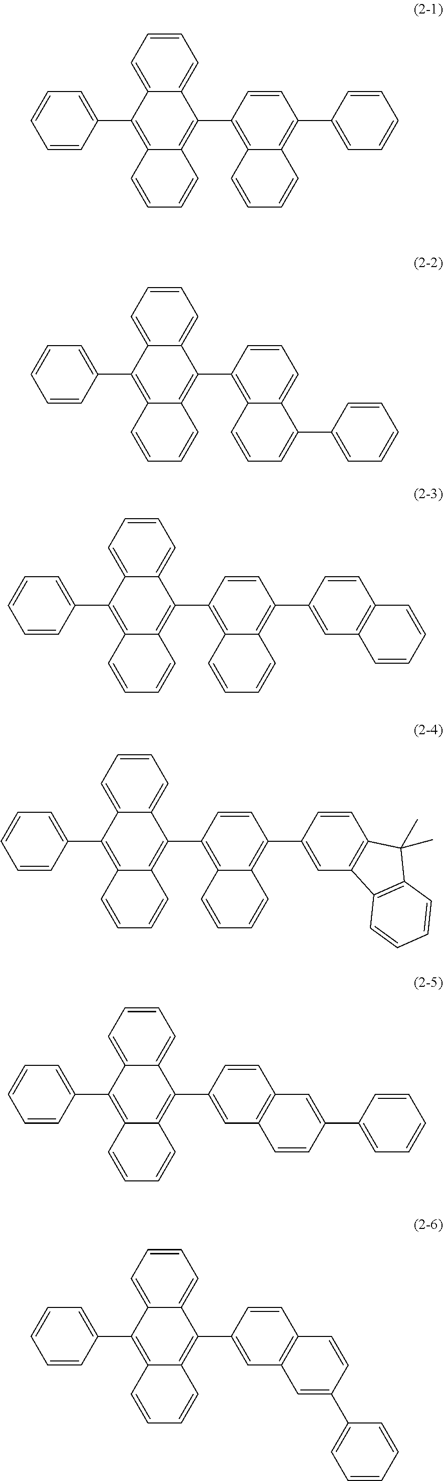

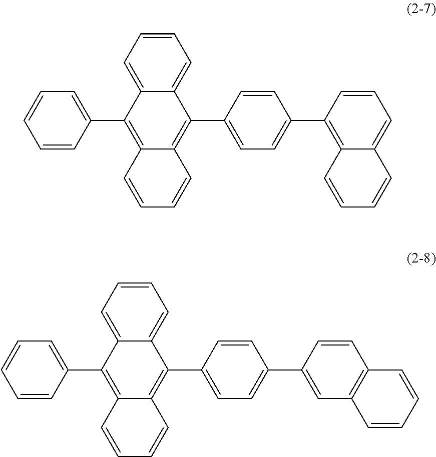

The electron transfer layer may include a metal or a metal complex.

The hole blocking layer may have a thickness of about 1 nm to about 100 nm.

The embodiments may be realized by providing an organic light emitting display including a substrate; gate lines on the substrate; data lines and a driving voltage line crossing the gate lines; a switching thin film transistor connected with the gate line and the data line; a driving thin film transistor connected with the switching thin film transistor and the driving voltage line; and an organic light emitting element connected with the driving thin film transistor, wherein the organic light emitting element includes a first compound represented by one of Chemical Formula 1-A to Chemical Formula 1-G, and a second compound represented by Chemical Formula 2:

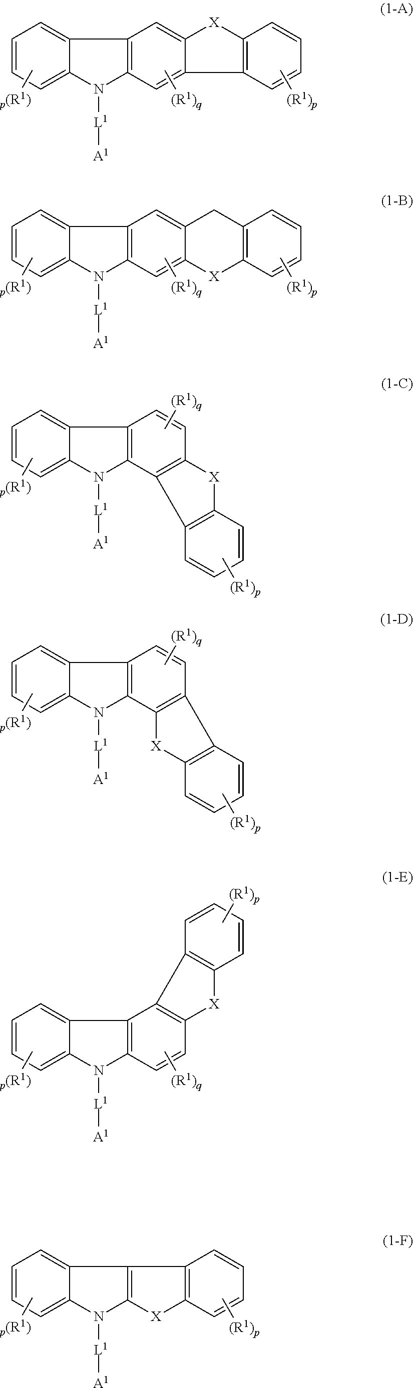

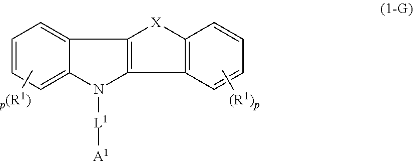

wherein, in Chemical Formula 1-A to Chemical Formula 1-G, A¹ is a substituted or unsubstituted C6 to C30 aromatic hydrocarbon group or a substituted or unsubstituted C6 to C30 condensed aromatic heterocyclic group, L¹ is a single bond, a substituted or unsubstituted C6 to C30 aromatic hydrocarbon group, a substituted or unsubstituted C6 to C30 condensed aromatic hydrocarbon group, a substituted or unsubstituted C2 to C30 aromatic heterocyclic group, or a substituted or unsubstituted C2 to C30 condensed aromatic heterocyclic group, X is S, O, N—R¹, or C(R¹)₂, each R¹ is independently, hydrogen, fluorine, a cyano group, a substituted or unsubstituted C1 to C20 alkyl group, a substituted or unsubstituted C1 to C20 alkoxy group, a substituted or unsubstituted C1 to C20 haloalkyl group, a substituted or unsubstituted C1 to C20 haloalkoxy group, a substituted or unsubstituted C1 to C10 alkylsilyl group, a substituted or unsubstituted C6 to C30 arylsilyl group, a substituted or unsubstituted C6 to C30 aromatic hydrocarbon group, a substituted or unsubstituted C6 to C30 condensed aromatic hydrocarbon group, a substituted or unsubstituted C2 to C30 aromatic heterocyclic group, or a substituted or unsubstituted C2 to C30 condensed aromatic heterocyclic group, p is an integer of 1 to 4, q is an integer of 1 to 2,

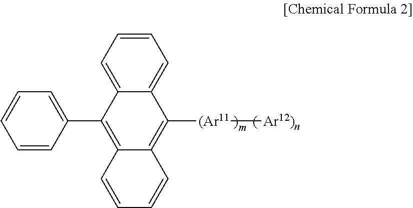

wherein, in Chemical Formula 2, each Ar¹¹ is independently a substituted or unsubstituted C5 to C30 arylene group or a substituted or unsubstituted C5 to C30 heteroarylene group, m is an integer of 0 to 3, such that when m is 0, Ar¹¹ is a single bond, each Ar¹² is independently a substituted or unsubstituted C5 to C30 aryl group or a substituted or unsubstituted C5 to C30 heteroaryl group, and n is an integer of 1 to 3.

The organic light emitting element may include an anode and a cathode that face each other; an emission layer between the anode and the cathode; a hole transfer layer between the anode and the emission layer; an electron transfer layer between the cathode and the emission layer; and a hole blocking layer between the electron transfer layer and the emission layer, the hole blocking layer may include the first compound, and the emission layer may include the second compound.

Ar¹¹ of the second compound may include a substituted or unsubstituted phenylene group or a substituted or unsubstituted naphthylene group.

The first compound may be represented by one of the following Chemical Formula 1-1 to Chemical Formula 1-7:

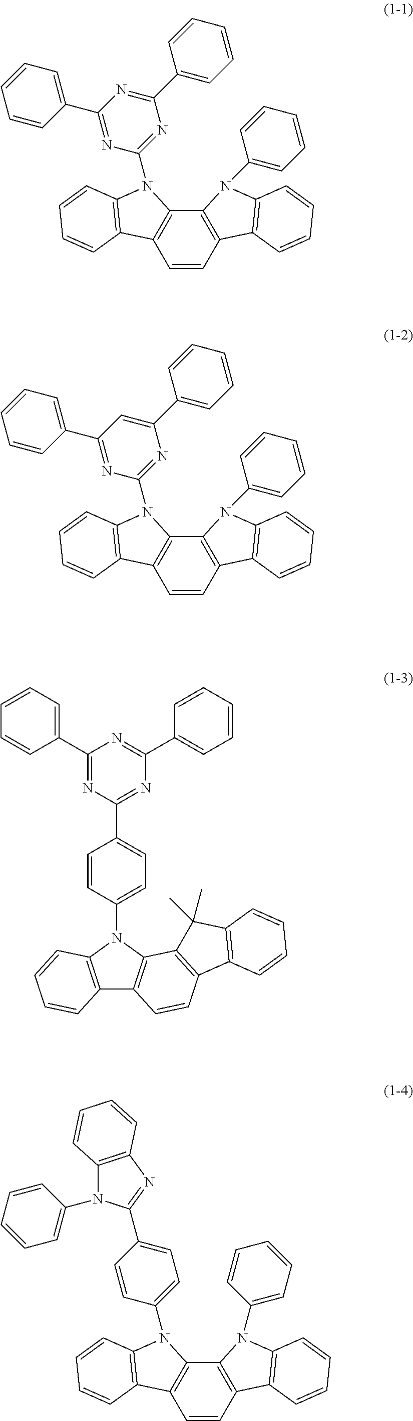 [SMILES: c1ccc(-c2nc(-c3ccccc3)nc(-n3c4ccccc4c4ccc5c6ccccc6n(-c6ccccc6)c5c43)n2)cc1 ; c1ccc(-c2cc(-c3ccccc3)nc(-n3c4ccccc4c4ccc5c6ccccc6n(-c6ccccc6)c5c43)n2)cc1 ; CC1(C)c2ccccc2-c2ccc3c4ccccc4n(-c4ccc(-c5nc(-c6ccccc6)nc(-c6ccccc6)n5)cc4)c3c21 ; c1ccc(-n2c(-c3ccc(-n4c5ccccc5c5ccc6c7ccccc7n(-c7ccccc7)c6c54)cc3)nc3ccccc32)cc1]

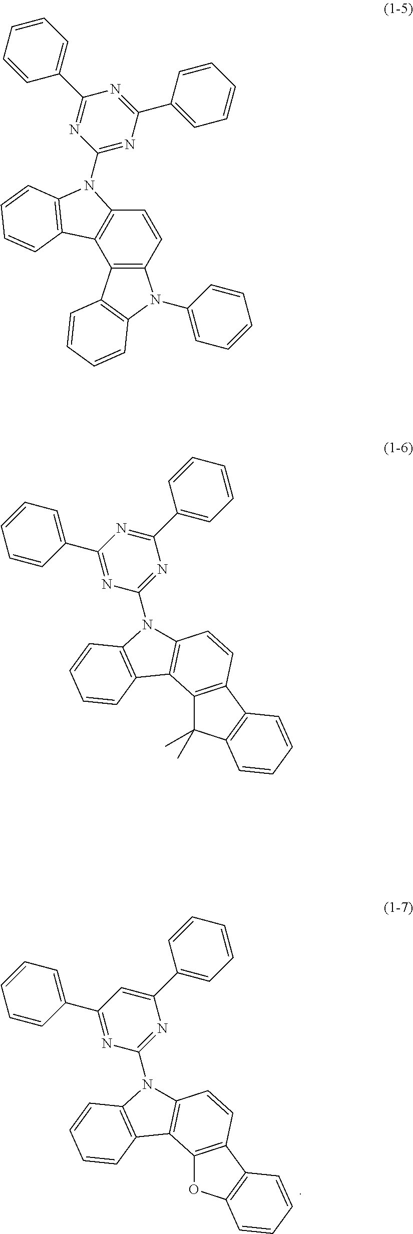 [SMILES: c1ccc(-c2nc(-c3ccccc3)nc(-n3c4ccccc4c4c5c6ccccc6n(-c6ccccc6)c5ccc43)n2)cc1 ; CC1(C)c2ccccc2-c2ccc3c(c21)c1ccccc1n3-c1nc(-c2ccccc2)nc(-c2ccccc2)n1 ; c1ccc(-c2cc(-c3ccccc3)nc(-n3c4ccccc4c4c5oc6ccccc6c5ccc43)n2)cc1 ; "."]

The second compound may be represented by one of the following Chemical Formula 2-1 to Chemical Formula 2-8:

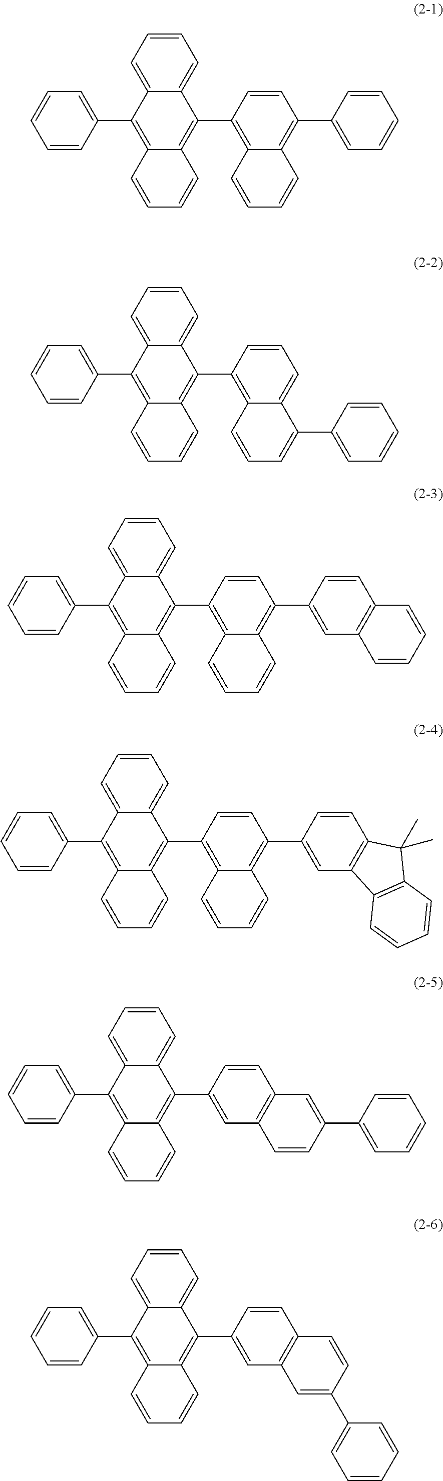

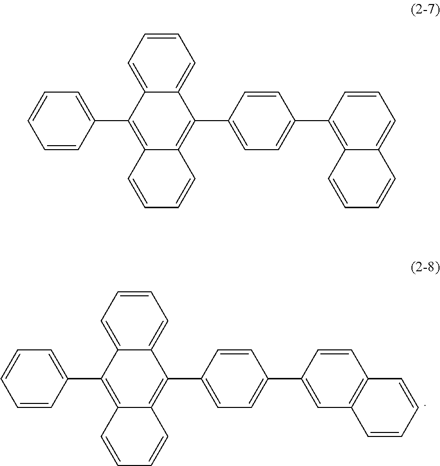

The electron transfer layer may include a metal or a metal complex.

The hole blocking layer may have a thickness of about 1 nm to about 100 nm.

### BRIEF DESCRIPTION OF THE DRAWINGS

Features will be apparent to those of skill in the art by describing in detail exemplary embodiments with reference to the attached drawings in which:

FIG. 1 illustrates a structure of an organic light emitting element according to an exemplary embodiment.

FIG. 2 illustrates a layout view of an organic light emitting device according to the exemplary embodiment.

FIG. 3 illustrates a cross-sectional view of the organic light emitting device of FIG. 2, taken along the line III-III.

FIG. 4 illustrates a cross-sectional view of the organic light emitting device of FIG. 2, taken along the line IV-IV.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

In the present specification, the term “substituted”, unless separately defined, means a substitution with a substituent selected from a group of deuterium, C1 to C6 alkyl groups, C6 to C36 aryl groups, C2 to C30 heteroaryl groups, C1 to C30 alkoxy groups, C2 to C30 alkenyl groups, C6 to C30 aryloxy groups, C3 to C30 silyloxy groups, C1 to C30 acyl groups, C2 to C30 acyloxy groups, C2 to C30 heteroacyloxy groups, C1 to C30 sulfonyl groups, C1 to C30 alkylthiol groups, C6 to C30 arylthiol groups, C1 to C30 heterocyclothiol groups, C1 to C30 phosphoric acid amide groups, C3 to C40 silyl groups, NR″R′″ (here, R″ and R′″ are respectively substituents selected from a group consisting of a hydrogen atom, C1 to C30 alkyl groups, and C6 to C30 aryl groups), a carboxylic acid group, a halogen group, a cyano group, a nitro group, an azo group, a fluorene group, and a hydroxyl group.

In addition, in the specification, the term “hetero”, unless separately defined, means a single functional group contains 1 to 3 heteroatoms selected from the group of B, N, O, S, P, Si, and P(═O), and carbon atoms as the remainder.

Further, among groups used in chemical formulae of the present specification, definition of a representative group is as follows. (The number of carbons that limits substituents is not restrictive, and does not limit characteristics of the constituents).

An unsubstituted C1 to C30 alkyl group may be a linear type or a branched type, and nonrestrictive examples of the unsubstituted C1 to C30 alkyl group may include methyl, ethyl, propyl, iso-propyl, sec-butyl, hexyl, iso-amyl, hexyl, heptyl, octyl, nonyl, dodecyl, and the like.

An unsubstituted C1 to C30 alkoxy group indicates a group having a structure of —OA (wherein A is an unsubstituted C1 to C30 alkyl group as described above). Non-limiting examples of the unsubstituted C1 to C30 alkoxy group may include a methoxy group, an ethoxy group, a propoxy group, an isopropyloxy group, a butoxy group, and a pentoxy group.

An unsubstituted C6 to C30 aryl group indicates a carbocyclic aromatic system containing at least one ring. At least two rings may be fused to each other or linked to each other by a single bond. The term “aryl” refers to an aromatic system, such as phenyl, naphthyl, or anthracenyl. Examples of the unsubstituted C6 to C30 aryl group may include a phenyl group, a tolyl group, a biphenyl group, a naphthyl group, an anthracenyl group, a terphenyl group, a fluorenyl group, a phenanthrenyl group, a pyrenyl group, a diphenylanthracenyl group, a diphenylanthracenyl group, a dinaphthylanthracenyl group, a pentacenyl group, a bromophenyl group, a hydroxyphenyl group, a stilbene group, an azobenzenyl group, and a ferrocenyl group.

An unsubstituted C2 to C30 heteroaryl group includes one, two, or three heteroatoms selected from a group consisting of B, N, O, S, P, Si, and P(═O). At least two rings may be fused to each other or linked to each other by a single bond. Examples of the unsubstituted C2 to C30 heteroaryl group may include a pyrazolyl group, an imidazolyl group, an oxazolyl group, a thiazolyl group, a triazolyl group, a tetrazolyl group, an oxadiazolyl group, a thidiazolyl group, a pyridinyl group, a triazinyl group, a carbazole group, an N-phenylcarbazole group, an indole group, a quinolyl group, an isoquinolyl group, a thiophene group, a dibenzothiophene group, and a dibenzimidazole group.

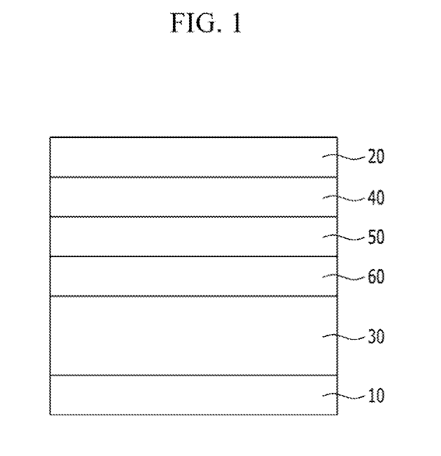

Hereinafter, an organic light emitting element according to an exemplary embodiment will be described in further detail. FIG. 1 illustrates a cross-sectional view of an organic light emitting element according to an exemplary embodiment.

Referring to FIG. 1, the organic light emitting element according to the exemplary embodiment may include an anode 10, a cathode 20 facing the anode 10, an emission layer 60 between the anode 10 and the cathode 20, a hole transport layer 30 between the anode 10 and the emission layer 60, an electron transport layer 40 between the cathode 20 and the emission layer 60, and a hole blocking layer 50 between the electron transport layer 40 and the emission layer 60.

A substrate (not shown) may be provided on a side of the anode 10 or on a side of the cathode 20. The substrate may be made of, e.g., an inorganic material such as glass, an organic material such as a polycarbonate, polymethylmethacrylate, polyethylene terephthalate, polyethylene naphthalate, a polyamide, polyether sulfone, or a combination thereof, or of a silicon wafer.

The anode 10 may be a transparent electrode or an opaque electrode. The transparent electrode may be, e.g., made of a conductive oxide such as indium tin oxide (ITO), indium zinc oxide (IZO), tin oxide (SnO₂), or a combination thereof, or a metal such as aluminum, silver, or magnesium with a thin thickness. The opaque electrode may be made of a metal, e.g., aluminum, silver, magnesium, or the like.

In an implementation, the anode 10 of the organic light emitting element according to the exemplary embodiment may have a structure in which a reflective layer is made of silver (Ag), aluminum (Al), chromium (Cr), molybdenum (Mo), tungsten (W), titanium (Ti), gold (Au), palladium (Pd), or an alloy film thereof, and an electrical reflective layer made of a transparent electrode material such as ITO, IZO, or ZnO, are layered.

The anode 10 may be formed using, e.g., a sputtering method, a vapor phase deposition method, an ion beam deposition method, an electron beam deposition method, or a laser ablation method.

The cathode 20 may include a material having a small work function for easy electron injection. For example, the material may be a metal such as magnesium, calcium, sodium, potassium, titanium, indium, yttrium, lithium, gadolinium, aluminum, silver, tin, lead, cesium, barium, or the like, or an alloy thereof, or a multi-layered structure material such as LiF/Al, LiO₂/Al, LiF/Ca, LiF/Al, and BaF₂/Ca. In an implementation, a metallic electrode such as aluminum may be used as the cathode 20.

For example, the conductive material used as the cathode 20 according to the exemplary embodiment may include magnesium, calcium, tin, lead, titanium, yttrium, lithium, ruthenium, manganese, aluminum, lithium fluoride, and the like, or an alloy thereof. The alloy may include magnesium/silver, magnesium/indium, lithium/aluminum, or the like. An alloy ratio of the alloys may be controlled based on a temperature of a deposition source, an atmosphere, a degree of vacuum, or the like, and an appropriate alloy ratio may be selected.

The anode 10 and the cathode 20 may be formed of two or more layers as desired.

The emission layer 60 may include a blue, red, or green emission material. In an implementation, the emission layer 60 may include a host and a dopant.

In an implementation, the emission layer 60 may include a second compound represented by Chemical Formula 2, below, as a host.

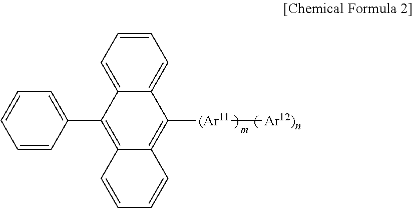

In Chemical Formula 2,

Ar¹¹ may be or may include, e.g., a substituted or unsubstituted C5 to C30 arylene group or a substituted or unsubstituted C5 to C30 heteroarylene group. In an implementation, Ar¹¹ may be or may include, e.g., a substituted or unsubstituted C6 to C30 arylene group or a substituted or unsubstituted C5 to C30 heteroarylene group. In an implementation, each Ar¹¹ may independently be or may independently include, e.g., a substituted or unsubstituted C6 to C30 arylene group or a substituted or unsubstituted C5 to C30 heteroarylene group.

m may be an integer of 0 to 3. When m is 0, Ar¹¹ may be a single bond. For example, a single bond may replace Ar¹¹.

Ar¹² may be or may include, e.g., a substituted or unsubstituted C5 to C30 aryl group or a substituted or unsubstituted C5 to C30 heteroaryl group. In an implementation, Ar¹² may be or may include, e.g., a substituted or unsubstituted C6 to C30 aryl group or a substituted or unsubstituted C5 to C30 heteroaryl group. In an implementation, each Ar¹² may independently be or may independently include, e.g., a substituted or unsubstituted C6 to C30 aryl group or a substituted or unsubstituted C5 to C30 heteroaryl group.

n may be an integer of 1 to 3. When m or n is 2 or more, the Ar¹¹ and Ar¹² may be the same as or different from one another.

In an implementation, the compound represented by Chemical Formula 2 may be represented by one of the following Chemical Formula 2-1 to Chemical Formula 2-97.

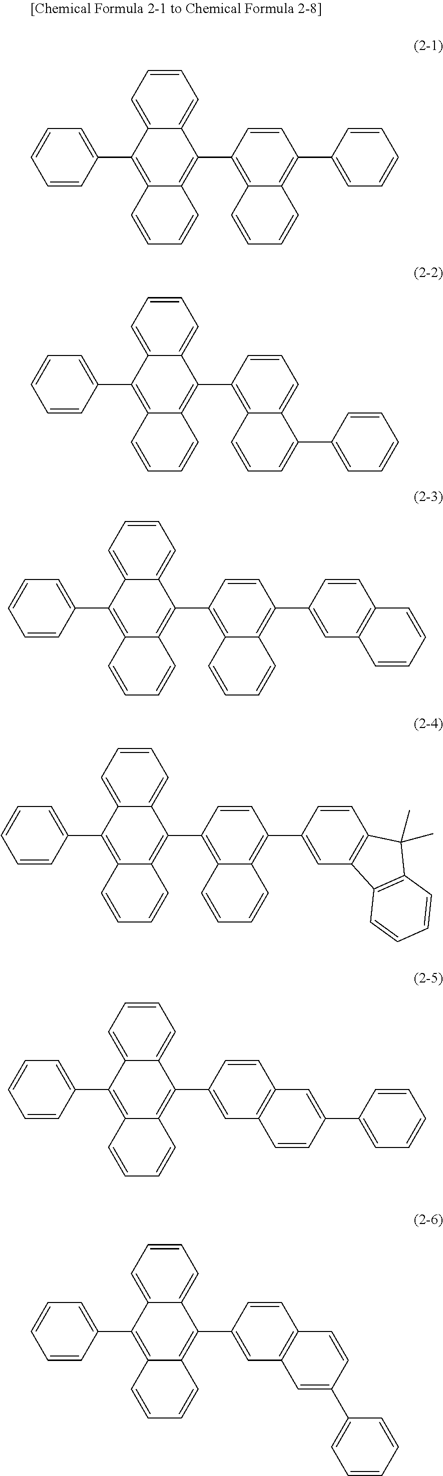

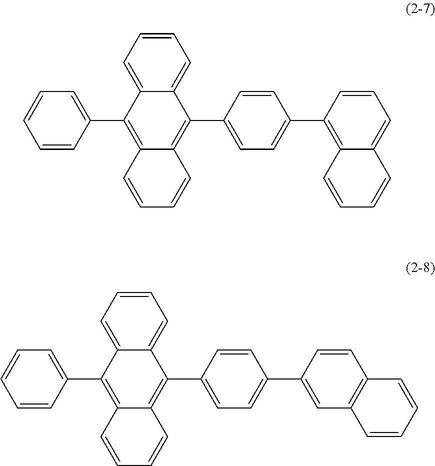

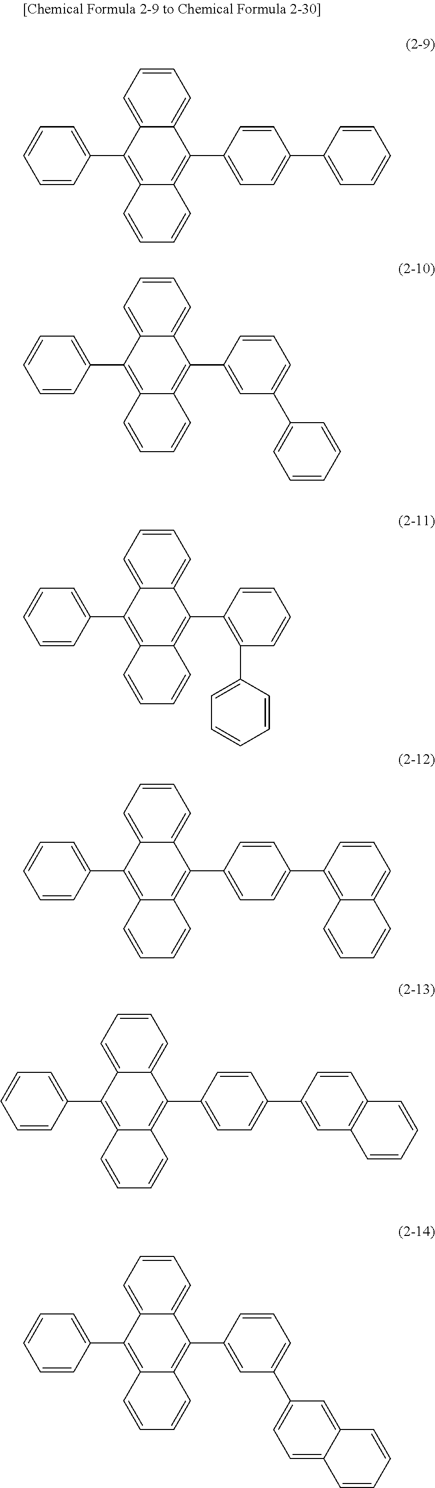

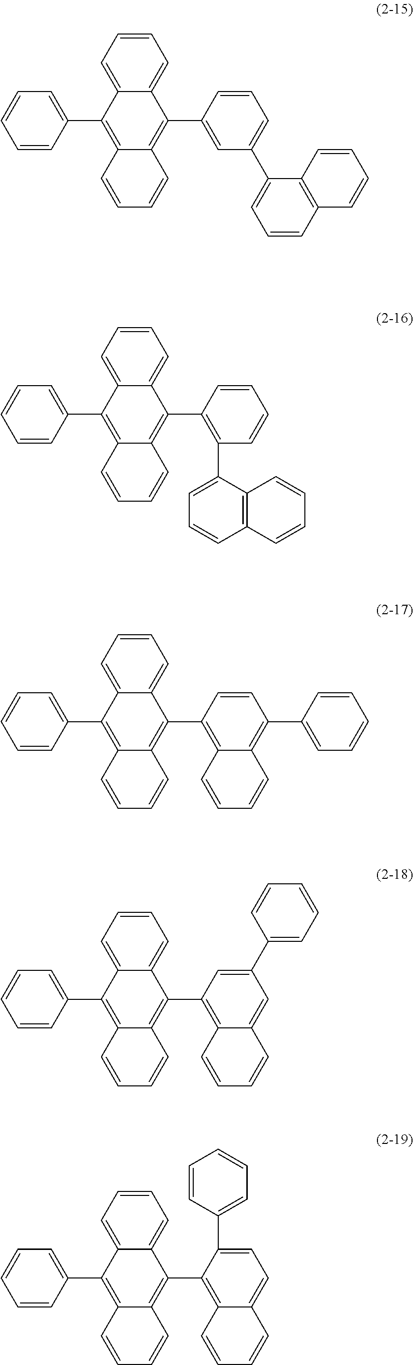

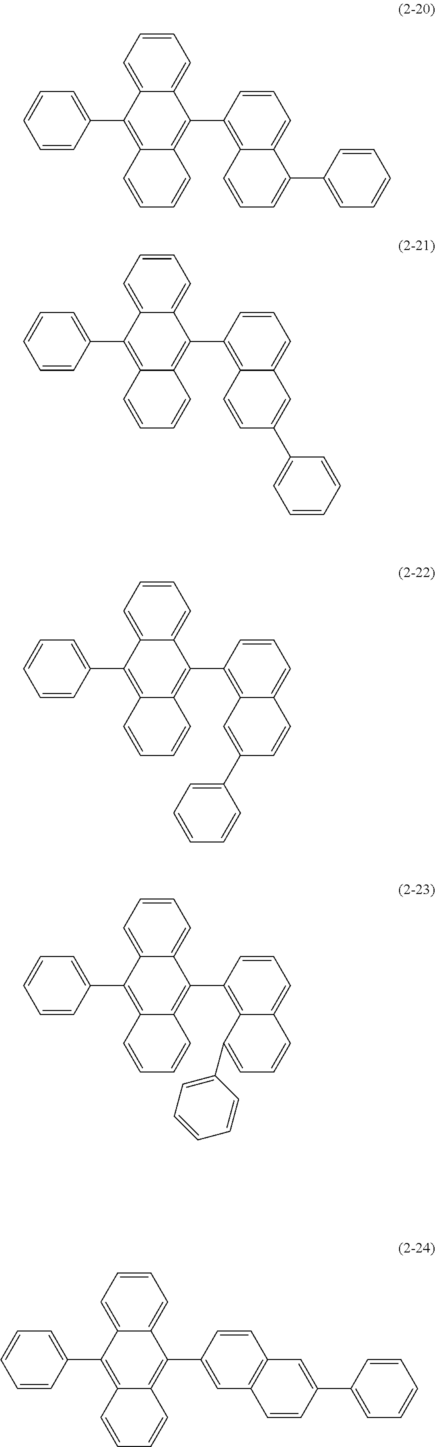

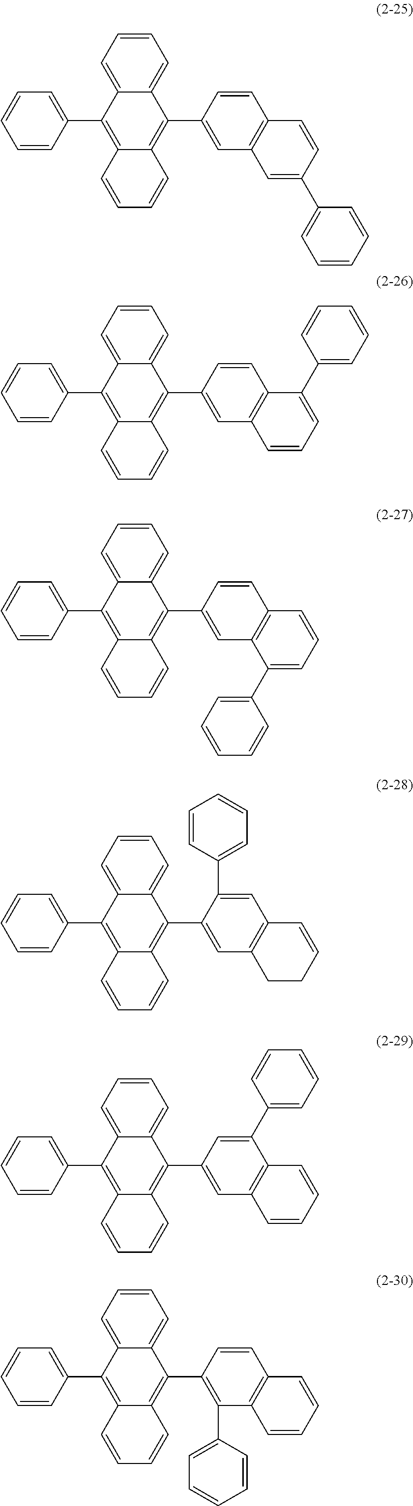

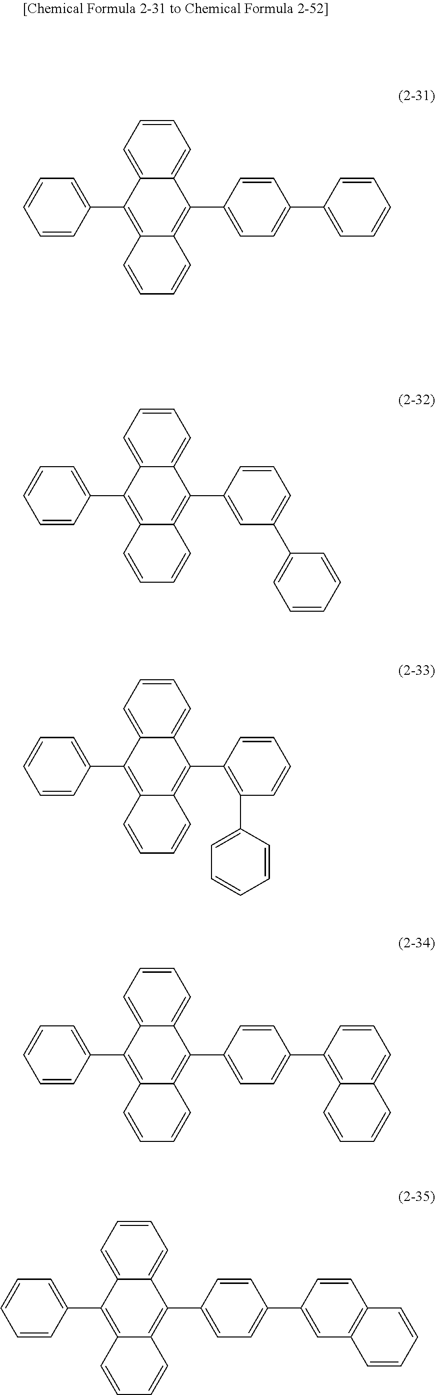

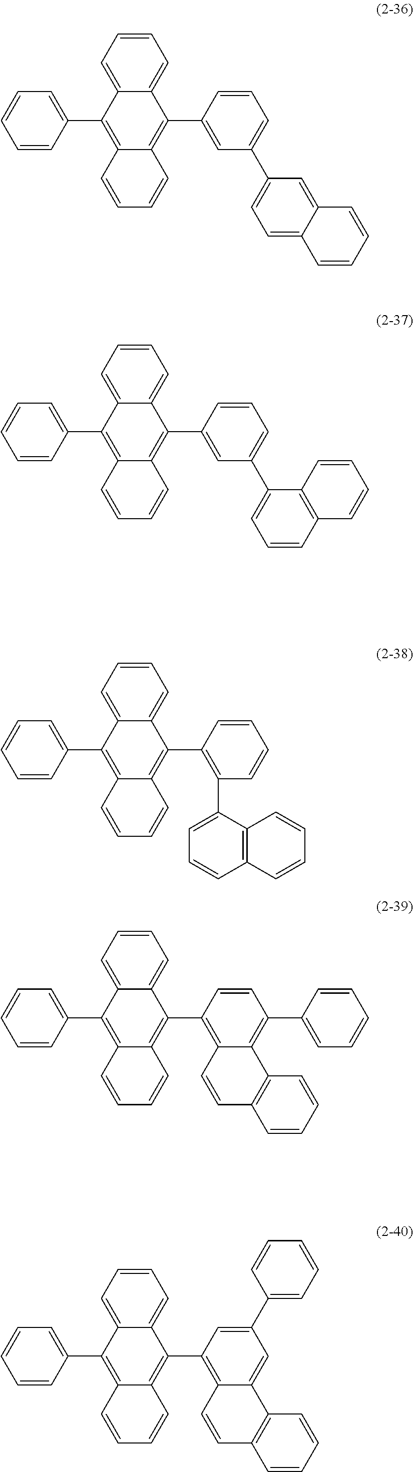

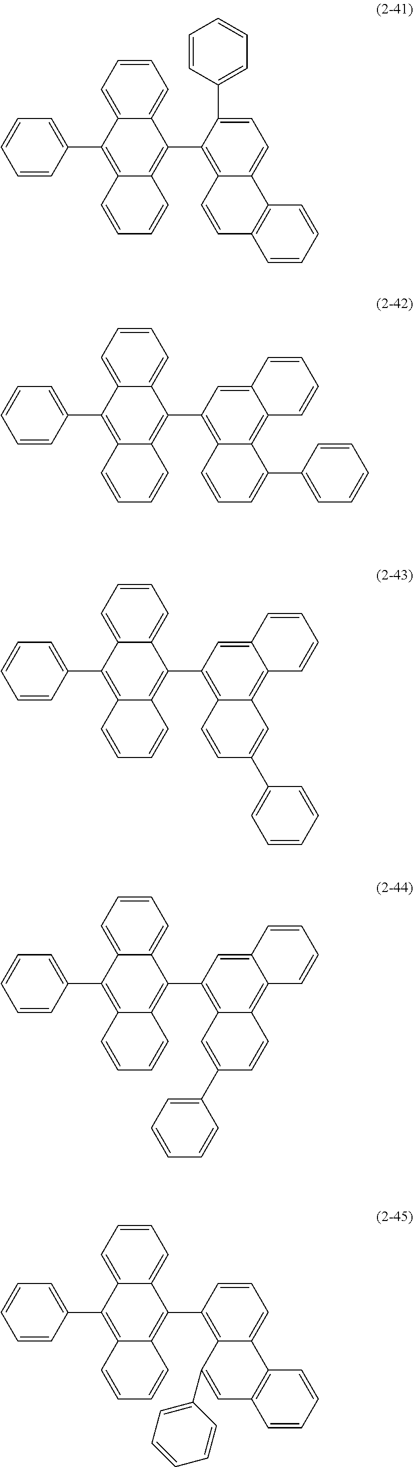

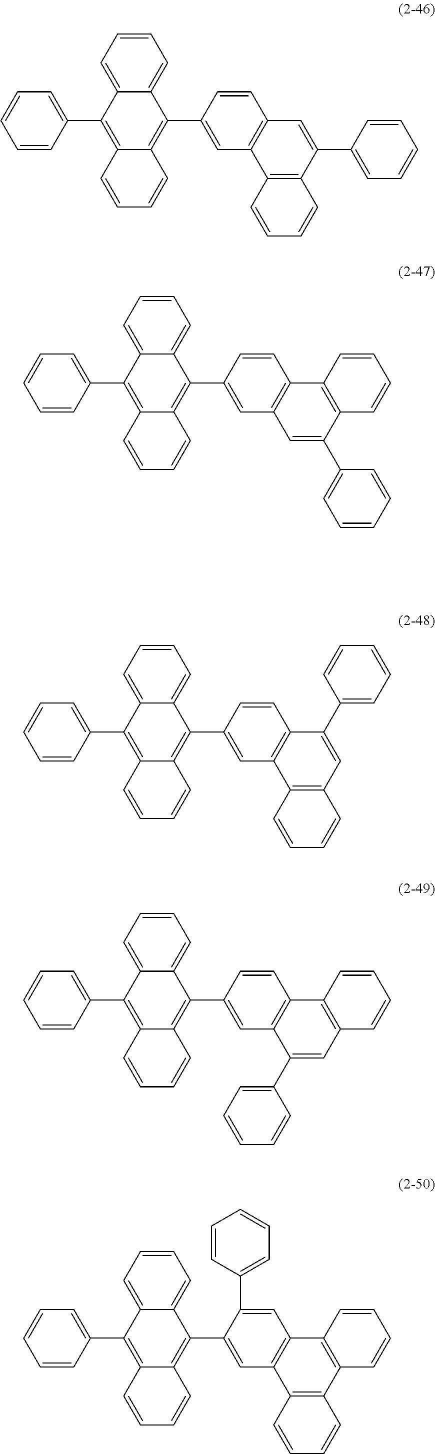

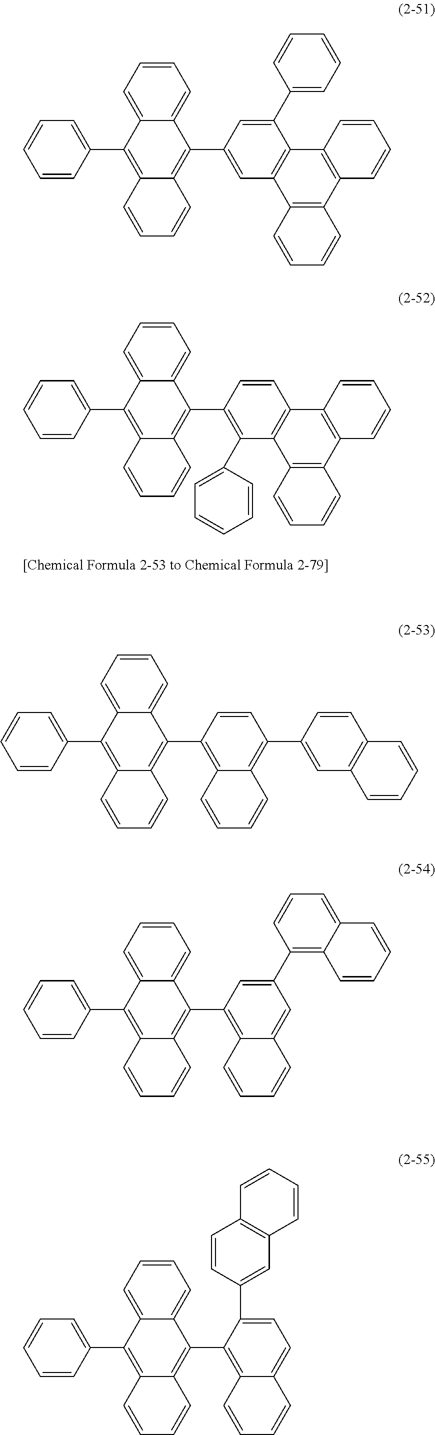

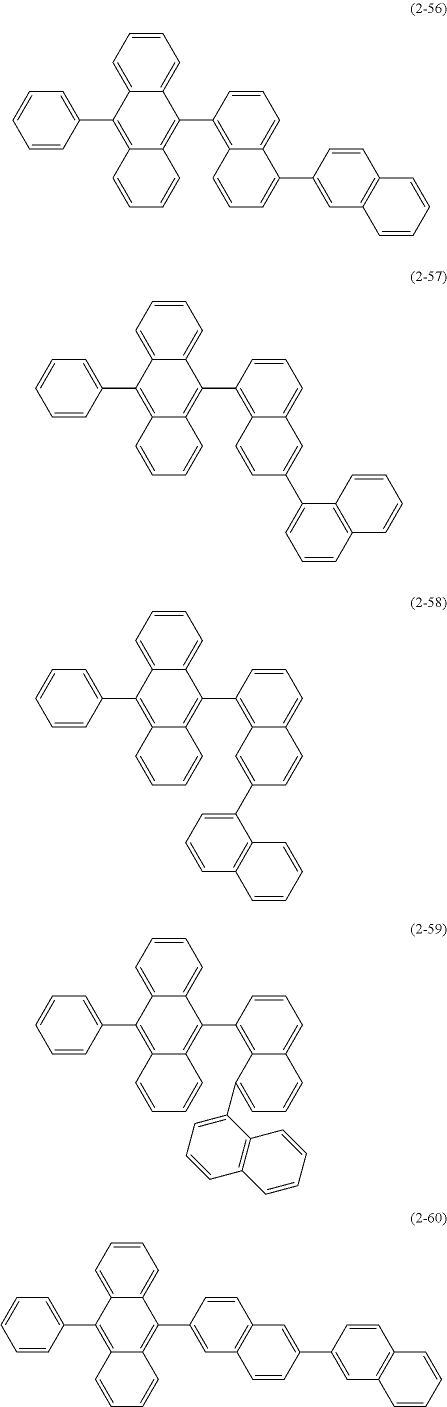

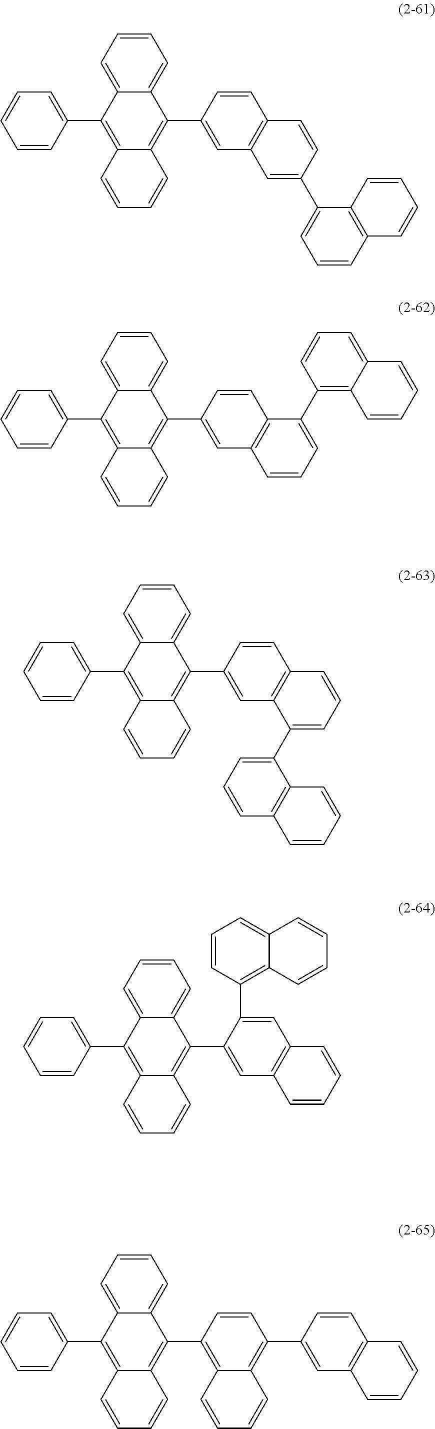

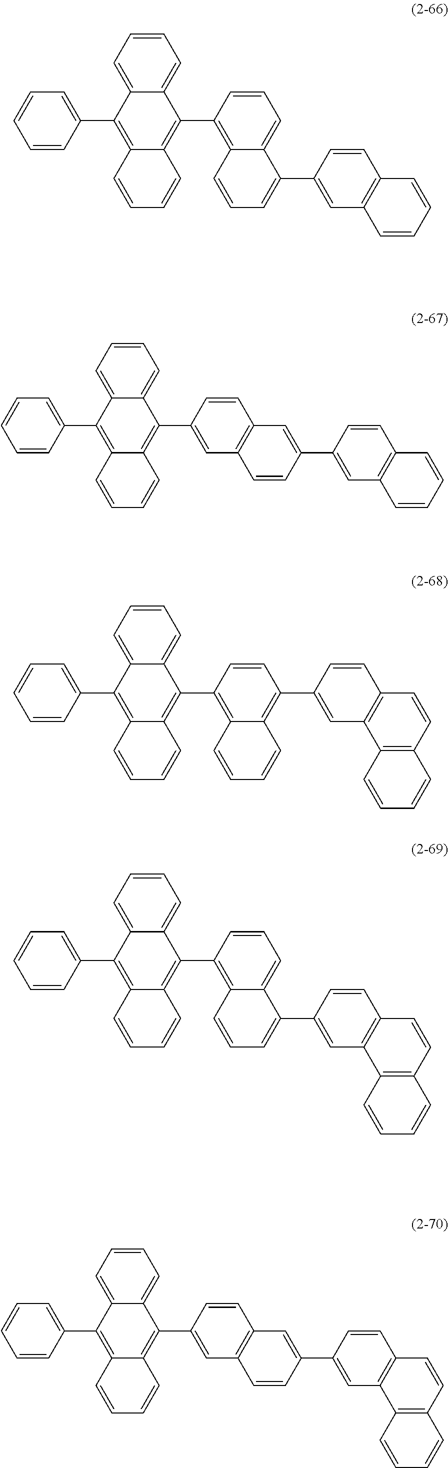

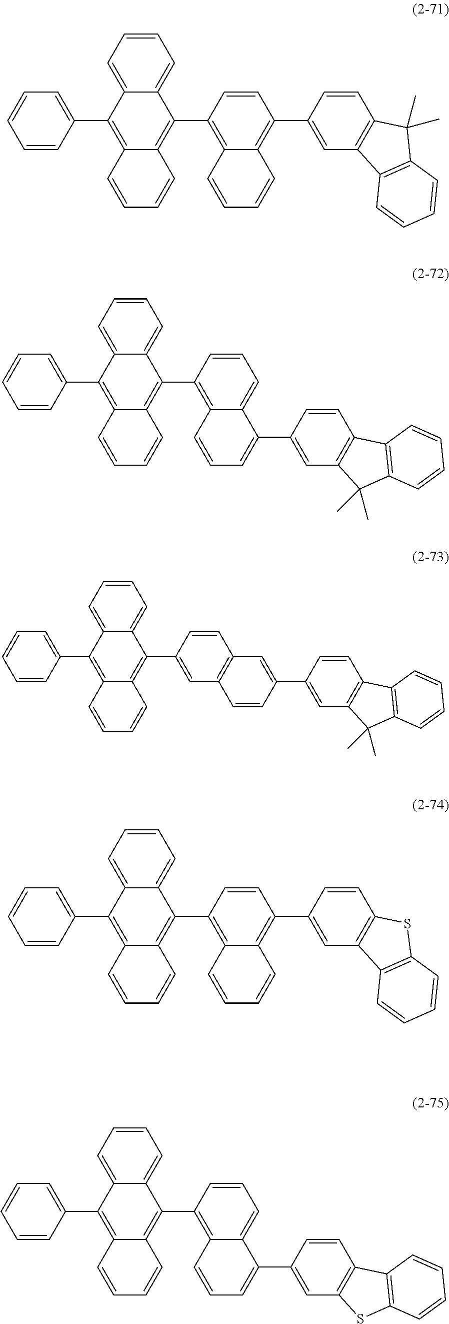

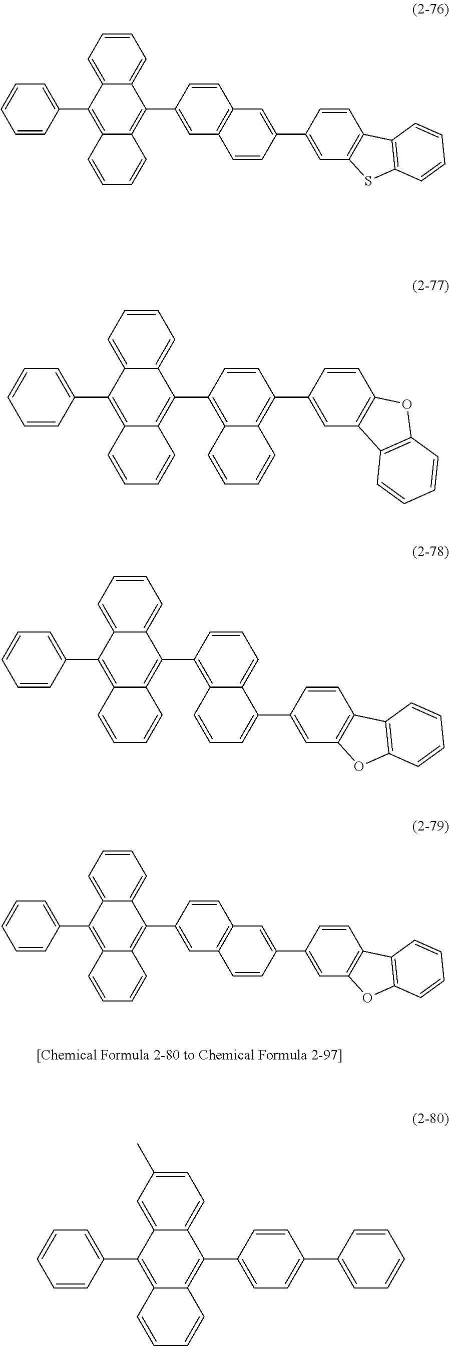

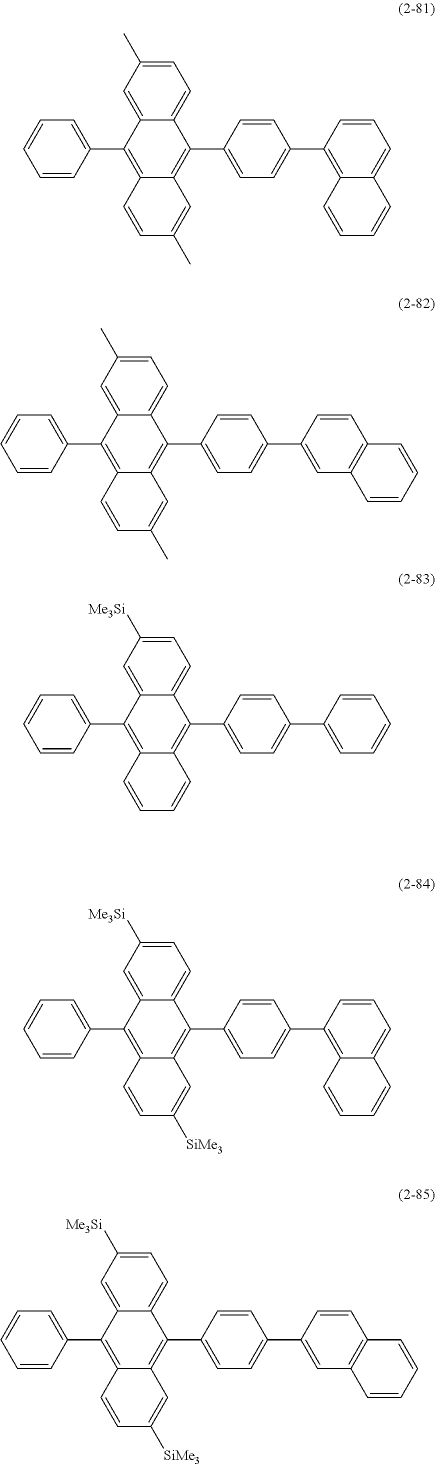

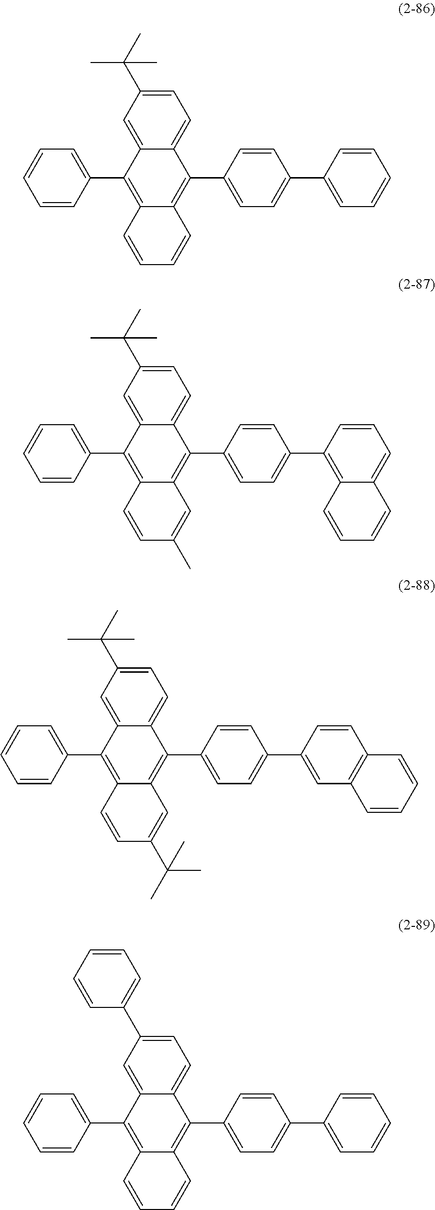

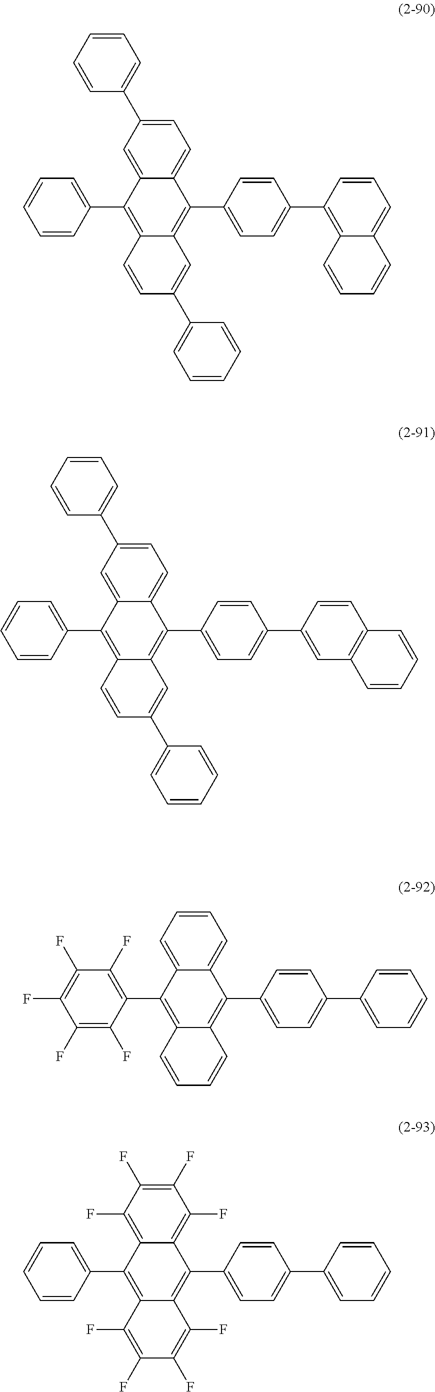

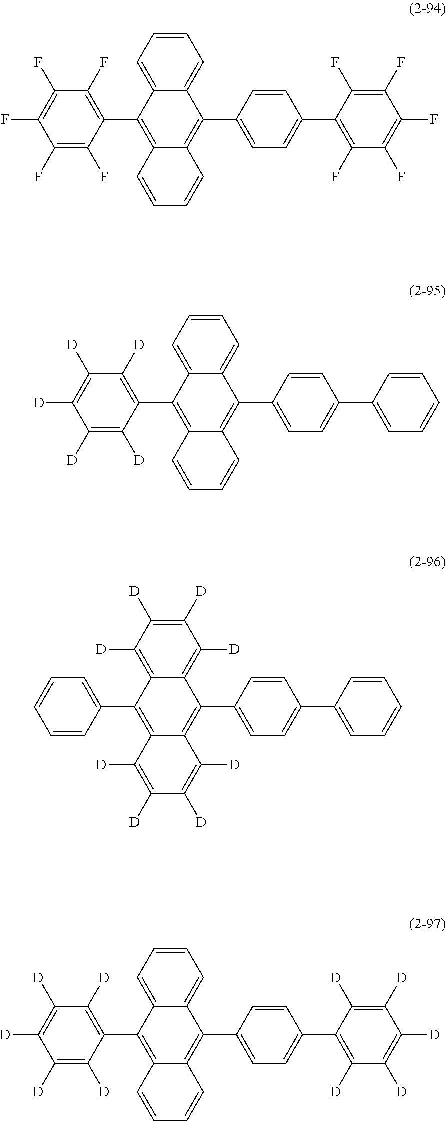 [SMILES: Fc1c(F)c(F)c(-c2ccc(-c3c4ccccc4c(-c4c(F)c(F)c(F)c(F)c4F)c4ccccc34)cc2)c(F)c1F ; [2H]c1c([2H])c([2H])c(-c2c3ccccc3c(-c3ccc(-c4ccccc4)cc3)c3ccccc23)c([2H])c1[2H] ; [2H]c1c([2H])c([2H])c2c(-c3ccc(-c4ccccc4)cc3)c3c([2H])c([2H])c([2H])c([2H])c3c(-c3ccccc3)c2c1[2H] ; [2H]c1c([2H])c([2H])c(-c2ccc(-c3c4ccccc4c(-c4c([2H])c([2H])c([2H])c([2H])c4[2H])c4ccccc34)cc2)c([2H])c1[2H]]

The emission layer 60 may additionally include a dopant material. For the dopant material, IDE102 and IDE105 (which may be purchased from Idemitsu Co., Ltd.) and C545T (which may be purchased from Hayashibara Co., Ltd.) may be used as a fluorescent dopant, and a red phosphorous dopant PtOEP, RD 61 of UDC Co., Ltd, a green phosphorous dopant Ir(ppy)3(py=2-phenylpyridine), a blue phosphorous dopant F₂Irpic, and a red phosphorous dopant RD 61 of UDC Co., Ltd. may be used as a phosphorous dopant.

In an implementation, as a dopant of the emission layer 60, Ir(ppy)3, Ir(ppy)2acac, (piq)2Ir(acac), Pt(OEP), or the like may be used.

In an implementation, the dopant may be included in an amount of about 0.01 to about 15 parts by weight, based on 100 parts by weight of the host.

In an implementation, the dopant may include a third compound represented by Chemical Formula 3.

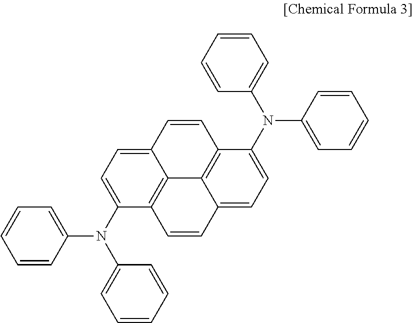 [SMILES: c1ccc(N(c2ccccc2)c2ccc3ccc4c(N(c5ccccc5)c5ccccc5)ccc5ccc2c3c54)cc1]

The third compound may be included in an amount of about 1 to about 10 parts by weight, based on 100 parts by weight of the host.

The third compound may be included in an amount of about 5 wt % or less in the emission layer 60, e.g., based on a total weight of the emission layer 60.

The second compound and the third compound may be deposited simultaneously when forming the emission layer.

The emission layer 60 may be formed using various methods, e.g., a vacuum deposition method, a spin coating method, a casting method, an LB method, or the like.

When an organic layer, e.g., the emission layer 60, is formed using the vacuum deposition method, the deposition conditions may vary according to the material that is used to form the organic layer, and the structure and thermal characteristics of the organic layer. For example, the deposition conditions may include a deposition temperature of about 100° C. to 500° C., a vacuum pressure of about 10⁻⁸ to about 10⁻³ torr, and/or a deposition speed of about 0.01 to about 100 Å/s.

When an organic layer, e.g., the emission layer 60, is formed using the spin coating method, the coating conditions may vary according to the material used to form the organic layer, and the structure and thermal characteristics of the organic layer. For example, the coating conditions may include a coating speed of about 2,000 rpm to about 5,000 rpm, and/or a thermal treatment temperature of about 80° C. to about 200° C. at which the solvent remaining after coating may be removed.

The hole transfer layer 30 may include a suitable hole transfer material, e.g., an arylene-diamine derivative, a starburst-based compound, a biphenyl-diamine derivative including a spiro group, and a ladder-type compound. In an implementation, the hole transfer layer 30 may include, e.g., a carbazole derivate including 4,4″,4″″-tris[(3-methylphenyl(phenyl)amino)]triphenylamine (m-MTDATA), 1,3,5-tris[4-(3-methylphenylphenylamine)phenyl]benzene (m-MTDATB), copper phthalocyanine (CuPc), N-phenylcarbazole, polyvinyl carbazole, or the like, and/or a suitable amine derivate including an aromatic condensed ring such as N,N′-bis(3-methylphenyl)-N,N′-diphenyl-[1,1-biphenyl]-4,4′-diamine (TPD), N,N′-di(naphthalene-1-yl)-N,N′-diphenyl benzidine (α-NPD), or the like.

In an implementation, the hole transport layer may include a fifth compound represented by Chemical Formula 5.

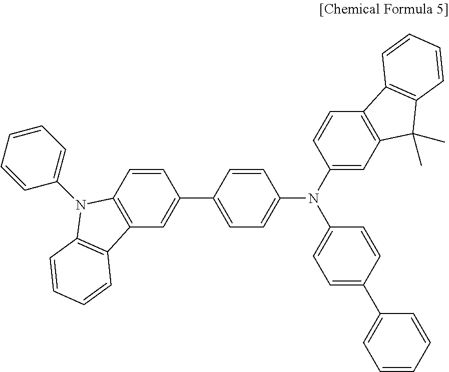 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21]

The hole transfer layer 30 may have a thickness of about 50 Å to about 1,000 Å, e.g., about 100 Å to about 600 Å. When the thickness of the hole transfer layer 30 satisfies the above-stated range, an excellent hole transfer characteristic may be acquired without a substantial increase of a driving voltage.

The hole transfer layer 30 may further include an assistant or auxiliary material for improvement of film conductivity. For example, the auxiliary material may be evenly or unevenly dispersed in the layers or may be variously deformed.

The hole transport layer 30 may be formed on an upper portion of the anode 10 using various methods, e.g., a vacuum deposition method, a spin coating method, a casting method, an LB method, or the like. When the vacuum deposition method and/or the spin coating method are used to form the hole transport layer 30, deposition conditions and coating conditions may vary according to a compound that is used to form the hole transport layer 30.

An electron blocking layer (not shown) may be additionally provided between the hole transfer layer 30 and the emission layer 60. In an implementation, a hole injection layer (not shown), which is a material that facilitates injection of holes from the anode, may be layered between the hole transfer layer 30 and the anode 10.

As the hole injection material, a suitable hole injection material such as TCTA, m-MTDATA, m-MTDAPB, Pani/DBSA (Polyaniline/Dodecylbenzene sulfonic acid), which is a soluble conductive polymer, or PEDOT/PSS (Poly(3,4-ethylenedioxythiophene)/Poly(4-styrenesulfonate): poly(3,4-ethylenedioxythiophene)/poly(4-styrenesulfonate)), Pani/CSA (Polyaniline/Camphor sulfonic acid), or PANI/PSS (Polyaniline)/Poly (4-styrenesulfonate)) may be used.

In an implementation, the hole injection layer may include a fourth compound represented by Chemical Formula 4.

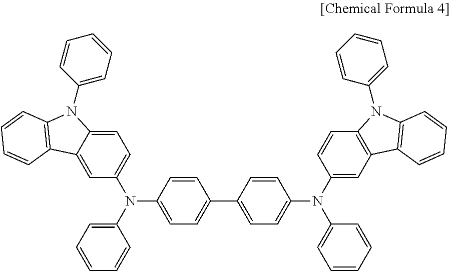 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

The hole injection layer may be formed using various methods, e.g., a vacuum deposition method, a spin coating method, a casting method, an LB method, or the like. When the hole injection layer is formed using the vacuum deposition method, the deposition conditions may vary according to the material that is used to form the hole injection layer, and the structure and thermal characteristics of the hole injection layer. For example, the deposition conditions may include a deposition temperature of about 100° C. to 500° C., a vacuum pressure of about 10⁻⁸ to about 10⁻³ torr, and/or a deposition speed of about 0.01 to about 100 Å/s.

When the hole injection layer is formed using the spin coating method, the coating conditions may vary according to the material used to form the hole injection layer, and the structure and thermal characteristics of the hole injection layer. For example, the coating conditions may include a coating speed of about 2,000 rpm to about 5,000 rpm, and/or a thermal treatment temperature of about 80° C. to about 200° C. at which the solvent remaining after coating may be removed.

The deposition conditions and the coating conditions of the hole injection layer may be similarly applied in forming of the hole transfer layer.

The electron transfer layer 40 may include, e.g., a quinoline derivative such as tris(8-hydroxyquinolinato)aluminum (Alq3), 3-(4-biphenyl)-4-phenyl-5-(4-tert-butylphenyl)-1,2,4-triazole (TAZ), (2-methyl-8-quninolinato)-4-phenylphenolate (BAlq), bis(10-hydroxybenzo(h)quinolinato)beryllium (Bebq2), or 4,7-diphenyl-1-10-phenanthroline (BPhen). In an implementation, lithium quinolate (Liq) may be doped to a compound selected from the group above. In an implementation, a doping density may be about 50 wt %.

The electron transfer layer 40 may have a thickness of about 100 Å to about 1,000 Å, e.g., about 200 Å to about 500 Å. Maintaining the thickness of the electron transfer layer 40 at about 100 Å or greater may help prevent a deterioration in an electron transfer characteristic. Maintaining the thickness of the electron transfer layer at about 1,000 Å or less may help prevent an increase in a driving voltage.

The electron transfer layer 40 may be formed using various methods, e.g., a vacuum deposition method, a spin coating method, a casting method, an LB method, or the like. The vacuum deposition method and the spin coating method may be used to form the electron transfer layer 40, and conditions thereof may be changed according to a used compound.

In addition, an electron injection layer (not shown), which may include a material that facilitates injection of electrons from a cathode, may be layered between the electron transfer layer and the cathode. The electron injection layer may include a suitable material, e.g., LiF, NaCl, CsF, Li₂O, BaO, or the like. The deposition conditions and the coating conditions of the electron injection layer may vary according to a compound that is used to form the electron injection layer. For example, the condition ranges for forming the electron injection layer may be almost the same as the conditions for forming the hole injection layer.

The hole blocking layer 50 according to the present exemplary embodiment may be provided between the electron transfer layer 40 and the emission layer 60. The hole blocking layer 50 may act as a barrier that blocks movement of holes. The hole blocking layer 50 may also be referred to as a buffer layer.

According to an embodiment, the hole blocking layer 50 may include a first compound represented by one of the following Chemical Formula 1-A to Chemical Formula 1-G.

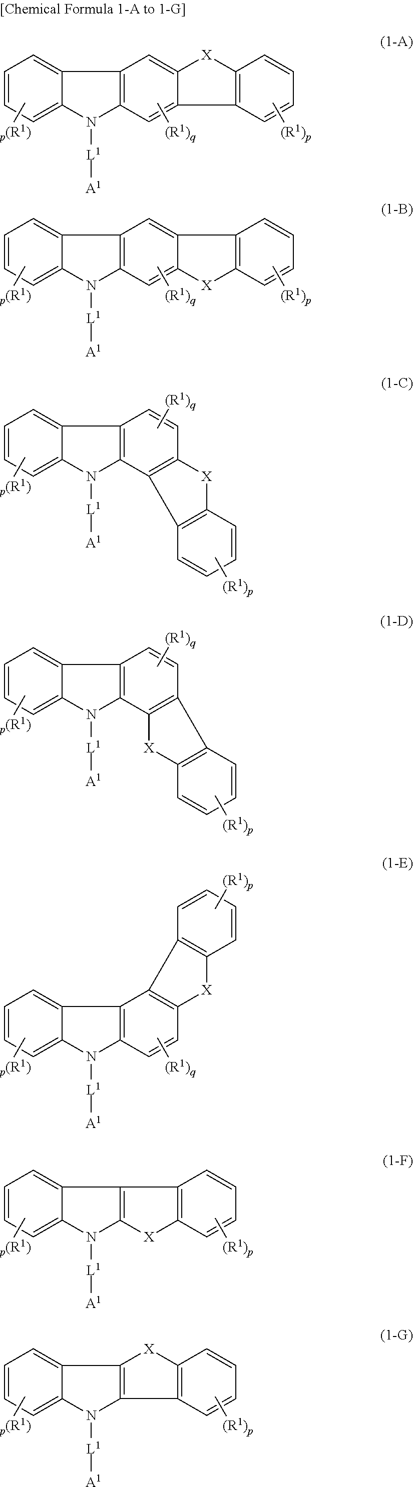

In Chemical Formula 1-A to 1-G,

A¹ may be or may include, e.g., a substituted or unsubstituted (ring-type) C6 to C30 (e.g., C6 to C30) aromatic hydrocarbon group or a substituted or unsubstituted (ring-type) C6 to C30 condensed aromatic heterocyclic group.

L¹ may be a connection group, and may be or include, e.g., a single bond, a substituted or unsubstituted C6 to C30 aromatic hydrocarbon group, a substituted or unsubstituted (ring-type) C6 to C30 condensed aromatic hydrocarbon group, a substituted or unsubstituted C2 to C30 aromatic heterocyclic group, or a substituted or unsubstituted (ring-type) C2 to C30 condensed aromatic heterocyclic group.

X may be S, O, N—R¹, or C(R¹)₂,

Each R¹ may independently be or include, e.g., hydrogen (H), fluorine (F), a cyano group (—CN), a substituted or unsubstituted C1 to C20 alkyl group, a substituted or unsubstituted C1 to C20 alkoxy group, a substituted or unsubstituted C1 to C20 haloalkyl group, a substituted or unsubstituted C1 to C20 haloalkoxy group, a substituted or unsubstituted C1 to C10 alkylsilyl group, a substituted or unsubstituted C6 to C30 arylsilyl group, a substituted or unsubstituted (ring-type) C6 to C30 aromatic hydrocarbon group, a substituted or unsubstituted (ring-type) C6 to C30 condensed aromatic hydrocarbon group, a substituted or unsubstituted (ring-type) C2 to C30 aromatic heterocyclic group, or a substituted or unsubstituted C2 to C30 condensed aromatic heterocyclic group.

p may be an integer of 1 to 4,

q may be an integer of 1 to 2, and

when p is an integer of 2 to 4 or q is 2, each R¹ may be the same as or different from one another.

In an implementation, the first compound may be represented by one of Chemical Formula 1-1 to Chemical Formula 1-7.

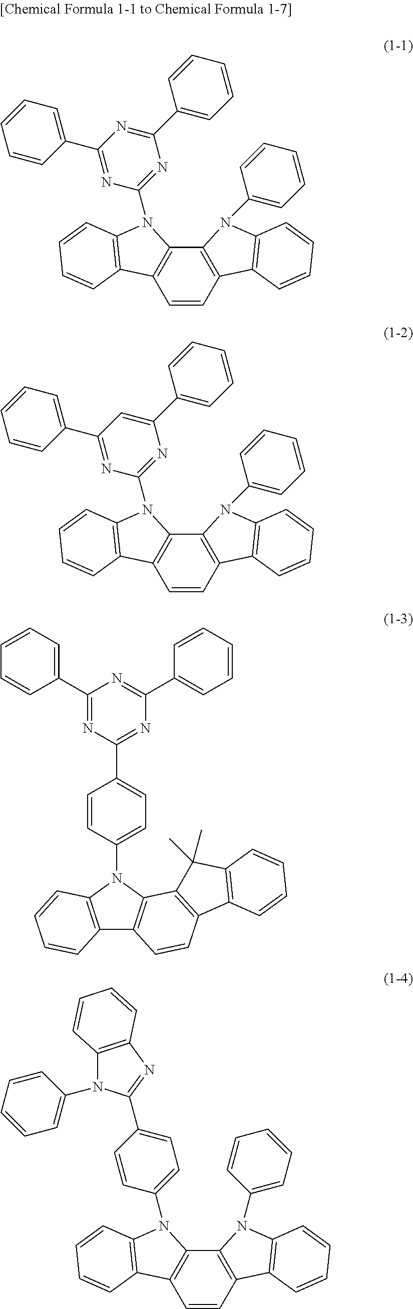

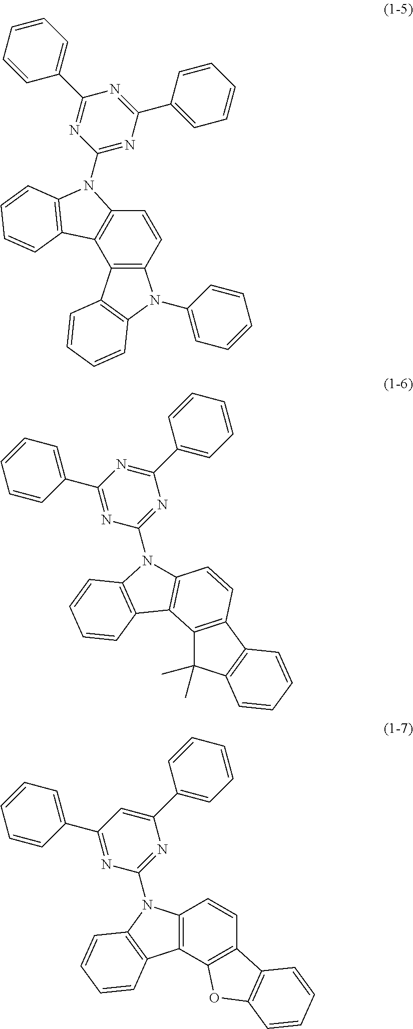

A thickness of the hole blocking layer 50 may be, e.g., about 10 Å to about 1,000 Å. Maintaining the thickness of the hole blocking layer 50 at about 10 Å or greater may help prevent a deterioration in hole blocking characteristics. Maintaining the thickness of the hole blocking layer 50 at about 1,000 Å or less may help prevent an increase in a driving voltage.

As described, in the organic light emitting element according to the exemplary embodiment, a carbazole-based or carbazole-containing compound (represented by Chemical Formula 1) may be used as or included in the hole blocking layer 50, and at the same time a phenyl-substituted anthracene-based or anthracene-containing compound (represented by Chemical Formula 2) may be included in the emission layer 60 of the organic light emitting element, and that carrier balance can be improved, efficiency of the organic light emitting element may be enhanced, and life span may be increased.

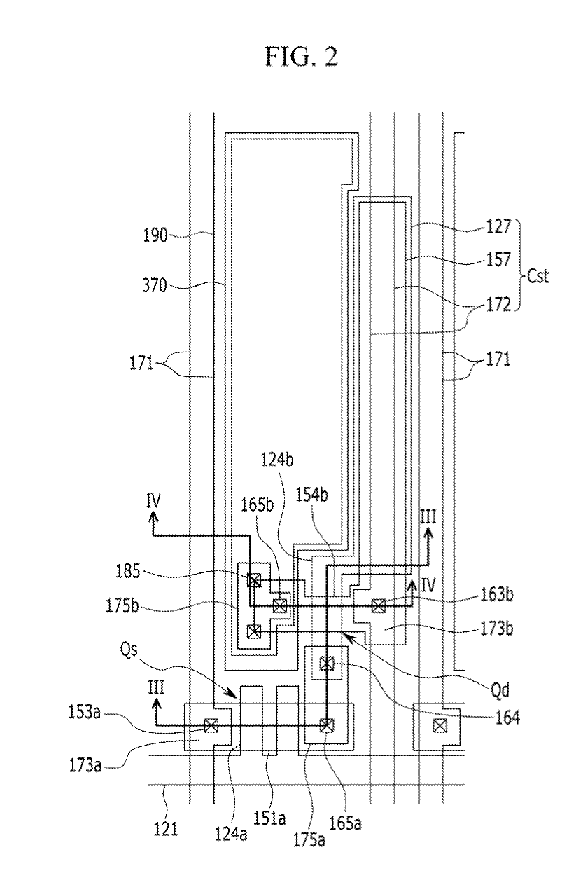

Next, an organic light emitting display including the organic light emitting element according to the exemplary embodiment will be described with reference to FIG. 2 to FIG. 4.

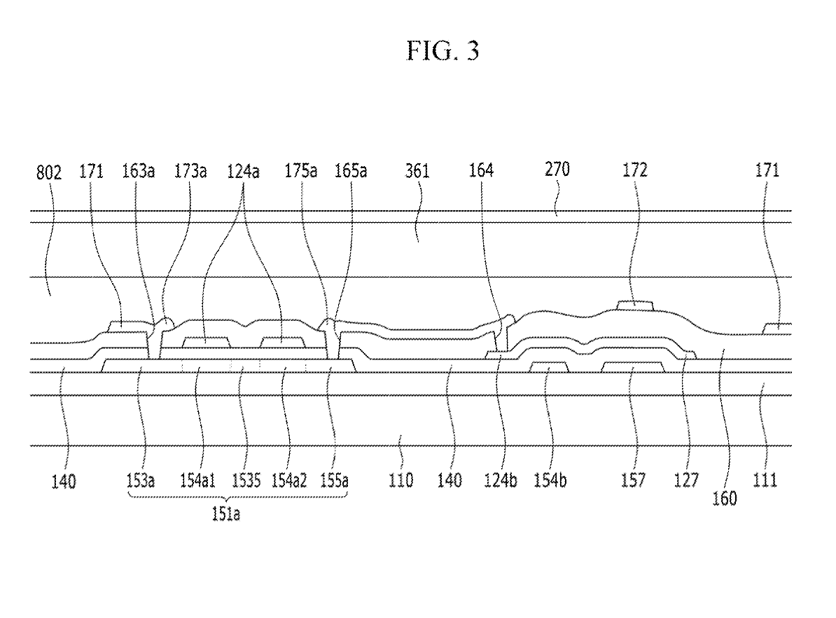

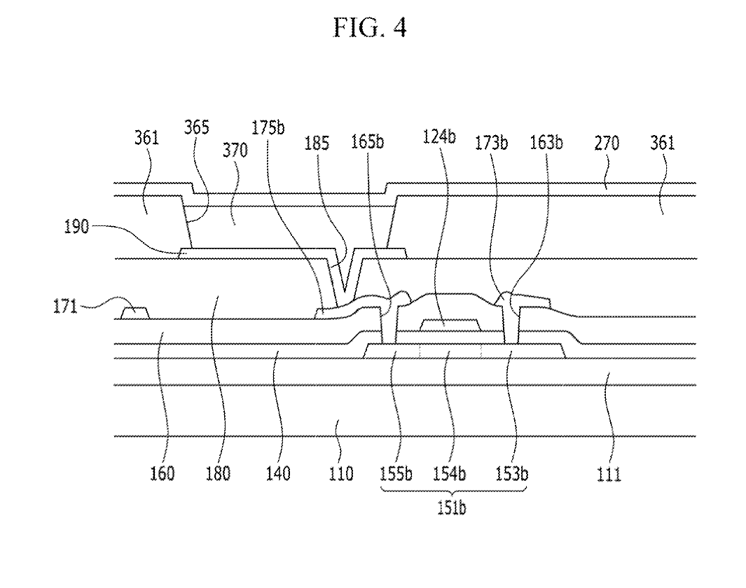

FIG. 2 illustrates a layout view of the organic light emitting display according to the exemplary embodiment. FIG. 3 illustrates a cross-sectional view of the organic light emitting display of FIG. 2, taken along the line III-III. FIG. 4 illustrates a cross-sectional view of the organic light emitting display of FIG. 2, taken along the line IV-IV.

A blocking layer 111 made of a silicon oxide or a silicon nitride may be formed on a substrate 110 made of transparent glass or the like. The blocking layer 111 may have a dual-layer structure.

A plurality of pairs of first and second semiconductor islands 151a and 151b may be formed on the blocking layer 111. The first and second semiconductor islands 151a and 151b may be made of polysilicon or the like. Each of the semiconductor islands 151a and 151b may include a plurality of extrinsic regions including an n-type or p-type conductive impurity, and at least one intrinsic region that hardly may include a conductive impurity.

In the first semiconductor island 151a, the extrinsic region may include a first source region 153a, a first drain region 155a, and an intermediate region 1535, and they may be respectively doped with an n-type impurity and are separated from each other. The intrinsic region may include a pair of first channel regions 154a1 and 154a2 provided between the extrinsic regions 153a, 1535, and 155a.

In the second semiconductor island 151b, the extrinsic region may include a second source region 153b and a second drain region 155b, and they may be doped with a p-type impurity and are separated from each other. The intrinsic region may include a second channel region 154b provided between the second source region 153b and the second drain region 155b, and a storage region 157 extended upward from the second drain region 153b.

The extrinsic region may further include a lightly-doped region (not shown) provided between the channel regions 154a1, 154a2, and 154b and the source and drain regions 153a, 155a, 153b, and 155b. Such a lightly-doped region may be replaced with an offset region that hardly includes an impurity.

In contrast, the extrinsic regions 153a and 155a of the first semiconductor island 151a may be doped with the p-type impurity, or the extrinsic regions 153b and 155b of the second semiconductor island 151b may be doped with the n-type impurity. The p-type conductive impurity may include boron (B), gallium (Ga), or the like, and the n-type conductive impurity may include phosphor (P), arsenic (As), or the like.

A gate insulating layer 140 made of a silicon oxide or a silicon nitride may be formed on the semiconductor islands 151a and 151b and the blocking layer 111.

A plurality of gate lines 121 including a first control electrode 124a and a plurality of gate conductors including a plurality of second control electrodes 124b may be formed on the gate insulating layer 140.

The gate lines 121 may transmit a gate signal and substantially extend in a horizontal direction. The first control electrode 124a may extend upward from the gate line 121 and crosses the first semiconductor island 151a. In this case, the first control electrode 124a may overlap the first channel regions 154a1 and 154a2. Each gate line 121 may include a wide end portion for connection with another layer or an external driving circuit. When a gate driving circuit generating the gate signal is integrated with the substrate 110, the gate line 121 may be extended and thus may be directly connected with the gate driving circuit.

The second control electrode 124b may be separated from the gate line 121 and may overlap the second channel region 154b of the second semiconductor island 151b. The second control electrode 124b may form a storage electrode 127 by being extended, and the storage electrode 127 may overlap the storage region 157 of the second semiconductor island 151b.

The gate conductors 121 and 124b may be made of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), or titanium (Ti). However, the gate conductors 121 and 124b may have a multilayered structure including at least two conductive layers having different physical properties. One of the conductive layers may be made of a metal having low resistivity, e.g., an aluminum-based metal, a silver-based metal, a copper-based metal, or the like so as to reduce a signal delay or a voltage drop. In contrast, the other conductive layer may be made of another material, e.g., a material having an excellent contact characteristic with indium tin oxide (ITO) and indium zinc oxide (IZO), for example, chromium (Cr), molybdenum (Mo), a molybdenum alloy, tantalum (Ta), titanium (Ti), or the like. A combination of the two conductive layers may include a chromium lower layer and an aluminum (alloy) upper layer, or an aluminum (alloy) lower layer and a molybdenum (alloy) upper layer. However, the gate conductors 121 and 124b may be made of various metals and conductors other than the above-stated metals and conductors.

Side surfaces of the gate conductors 121 and 124b may be inclined with an inclination angle of about 30° to 80°.

An interlayer insulating film 160 may be formed on the gate conductors 121 and 124b. The interlayer insulating layer 160 may be made of an inorganic insulator such as a silicon nitride or a silicon oxide, an organic insulator, a low-dielectric insulator, or the like. A dielectric constant of the low-dielectric insulator may be about 4.0 or less, and —Si:C:O, a-Si:O:F, or the like formed through plasma enhanced chemical vapor deposition (PECVD) may be examples of such a low-dielectric insulator. The interlayer insulating layer 160 may be formed of an organic insulator having photosensitivity, and the interlayer insulating layer 160 may have a flat surface.

A plurality of contact holes 164 exposing the second control electrode 124b may be formed in the interlayer insulating layer 160. In addition, a plurality of contact holes 163a, 163b, 165a, and 165b exposing the source and drain regions 153a, 153b, 155a, and 155b may be formed in the interlayer insulating layer 160.

A plurality of data conductors including data lines 171, driving voltage lines 172, and first and second output electrodes 175a and 175b may be formed on the interlayer insulating layer 160.

The data lines 171 may transmit a data signal and substantially extend in a vertical direction to cross the gate lines 121. Each data line 171 may include a plurality of first input electrodes 173a connected with the first source region 153a through the contact hole 163a, and may include a wide end portion for connection with another layer or an external driving circuit. When a data driving circuit generating the data signal is integrated with the substrate 110, the data line 171 may be extended and then connected with the data driving circuit.

The driving voltage lines 172 may transmit a driving voltage and substantially extend in a vertical direction to cross the gate line 121. Each of the driving voltage lines 172 may include a plurality of second input electrodes 173b connected with the second source region 153b through the contact hole 163b. The driving voltage lines 172 may overlap the storage electrode 127, and they may be connected with each other.

The first output electrode 175a may be separated from the data line 171 and the driving voltage line 172. The first output electrode 175a may be connected with the first source region 155a through the contact hole 165a, and may be connected with the second control electrode 124b through the contact hole 164.

The second output electrode 175b may be separated from the data line 171, the driving voltage line 172, and the first output electrode 175a, and may be connected with the second source 155b through the contact hole 165b.

The data conductors 171, 172, 175a, and 175b may be made of a refractory material such as molybdenum, chromium, tantalum, titanium, or the like, or an alloy thereof, and/or may have a multilayer structure formed of a conductive layer (not shown) such as a refractory metal or the like and a low-resistive material conductive layer (not shown). An example of the multilayered structure may include a double layer of a chromium or molybdenum (alloy) lower layer and an aluminum (alloy) upper layer, or a triple layer of a molybdenum (alloy) lower layer, an aluminum (alloy) middle layer, and a molybdenum (alloy) upper layer. However, the data conductors 171, 172, 175a, and 175b may be made of various metals and conductors other than the above-stated metals and conductors.

Like the gate conductors 121 and 121b, the data conductors 171, 172, 175a, and 175b may also have side surfaces that are inclined preferably at about 30° to 80° with respect to the substrate 110.

A passivation layer 180 may be formed on the data conductors 171, 172, 175a, and 175b. The passivation layer 180 may be made of an inorganic material, an organic material, a low dielectric constant insulating material, or the like.

A plurality of contact holes 185 exposing the second output electrode 175b may be formed in the passivation layer 180. A plurality of contact holes (not shown) exposing an end portion of the data line 171 may be formed in the passivation layer 180, and a plurality of contact holes (not shown) exposing an end portion of the gate line 121 may be formed in the passivation layer 180 and the interlayer insulating layer 160.

A plurality of pixel electrodes 190 may be formed on the passivation layer 180. Each pixel electrode 190 may be physically and electrically connected with the second output electrode 175b through the contact hole 185, and may be made of a transparent conductive material such as ITO or IZO or a reflective metal such as aluminum, silver, or an alloy thereof.

A plurality of contact assistants (not shown) or a plurality of connecting members (not shown) may be formed on the passivation layer 180, and they may be connected with the gate line 121 and an exposed end portion of the data line 171.

A partition 361 may be formed on the passivation layer 180. The partition 361 may define openings by surrounding a periphery of an edge of the pixel electrode 190 like a bank, and may be made of an organic insulator or an inorganic insulator. The partition 361 may be made of a photoresist including a black pigment, and in this case, the partition 361 may function as a light blocking member and may be formed through a simple process.

An organic emission layer 370 may be formed on the pixel electrode 190 and a common electrode 270 may be formed on the organic emission layer 370. In this way, an organic light emitting element including the pixel electrode 190, the organic emission layer 370, and the common electrode 270 may be formed.

The organic light emitting element may be the same as the above-described organic light emitting element. For example, the organic light emitting element may have a lamination structure including anode/emission layer/cathode, anode/hole transfer layer/emission layer/electron injection layer/cathode, anode/hole transfer layer/emission layer/hole blocking layer/electron transfer layer/cathode, or anode/hole transfer layer/emission layer/hole blocking layer/electron transfer layer/cathode.

In this case, the pixel electrode 190 may be an anode which is a hole injection electrode, and the common electrode 270 may become a cathode which is an electron injection electrode. In an implementation, according to a driving method of the organic light emitting device, the pixel electrode 190 may be a cathode and the common electrode 270 may be an anode. The hole and electron may be injected into the organic emission layer 370 from the pixel electrode 190 and the common electrode 270, respectively, and an exciton generated by coupling the injected hole and electron may fall from an excited state to a ground state to emit light.

The common electrode 270 may be formed on the organic emission layer 370. The common electrode 270 may receive a common voltage, and may be made of a reflective metal including calcium (Ca), barium (Ba), magnesium (Mg), aluminum (Al), silver (Ag), or the like, or a transparent conductive material such as ITO or IZO.

The emission layer, the hole blocking layer, and the electron injection layer may be the same as those described above. For example, the first compound, which is the carbazole-based or carbazole-containing compound, may be included as or in a hole blocking layer of the organic light emitting element, and the second compound, which is the anthracene-based or anthracene-containing compound, may be included in the emission layer, e.g., as a host.

In such an organic light emitting device, the first semiconductor island 151a, the first control electrode 124a connected to the gate line 121, and the first input electrode 173a and the first output electrode 175a connected to the data line 171 may form a switching thin film transistor Qs, and a channel of the switching thin film transistor Qs may be formed in channel regions 154a1 and 154a2 of the first semiconductor island 151a. The second semiconductor island 151b, the second control electrode 124b connected to the first output electrode 175a, the second input electrode 173b connected to the driving voltage line 172, and the second output electrode 175b connected to the pixel electrode 190 may form a driving thin film transistor Qd, and a channel of the driving thin film transistor Qd may be formed in the channel region 154b of the second semiconductor island 151b. The pixel electrode 190, the organic light emitting member 370, and the common electrode 270 may form an organic light emitting diode, and the pixel electrode 190 may become an anode and the common electrode 270 may become a cathode, or the pixel electrode 190 may become a cathode and the common electrode 270 may become an anode. The storage electrode 127, the driving voltage line 172, and the storage region 157 that overlap each other may form a storage capacitor Cst.

The switching thin film transistor Qs may transmit a data signal of the data line 171 in response to a gate signal of the gate line 121. When receiving the data signal, the driving thin film transistor Qd may flow a current that depends on a voltage difference between the second control electrode 124b and the second input electrode 173b. The voltage difference between the second control electrode 124b and the second input electrode 173b may be charged to the storage capacitor Cst and then maintained even after the switching thin film transistor Qs is turned off. The organic light emitting diode may display an image by emitting light of which the strength varies depending on a current of the driving thin film transistor Qd.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Example 1

An indium tin oxide (ITO) transparent electrode was formed with a thickness of 120 nm on a glass substrate. The glass substrate was then cleaned using ultrasonic waves, and a pretreatment process (i.e., UV—O₃ treatment or heat treatment) was performed.

A compound represented by Chemical Formula 4 was deposited with a thickness of 50 nm as a hole injection layer on a pre-treated anode, and then a compound represented by Chemical Formula 5 was deposited with a thickness of 45 nm as a hole transfer layer thereon. Then, a compound of Chemical Formula 3, which is a doping material, was simultaneously deposited with a concentration of 5 wt % to a compound of Chemical Formula 2-1, which is a host material, such that an emission layer having a thickness of 30 nm was formed.

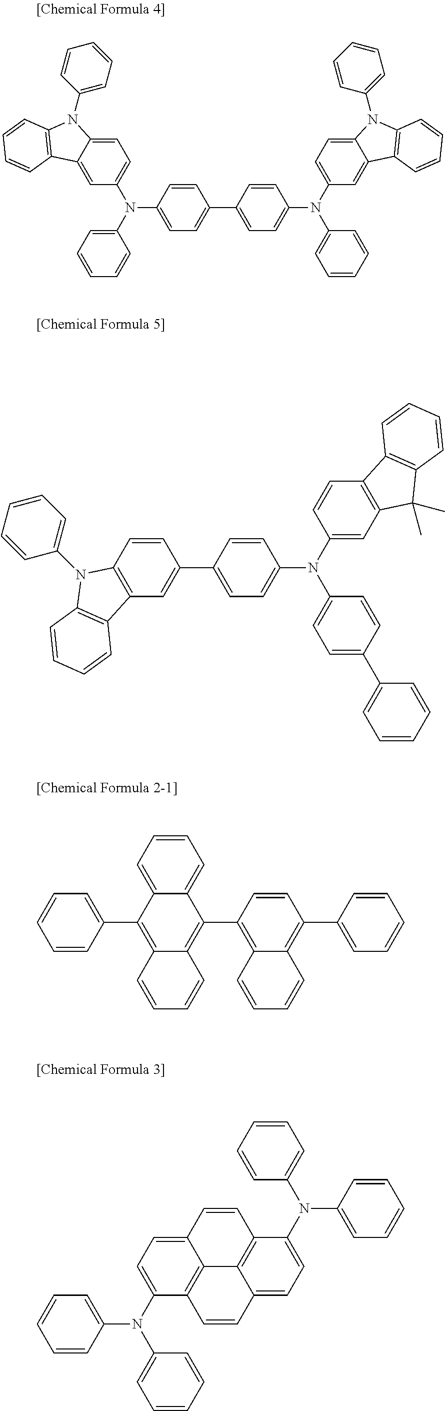

Next, as a hole blocking layer, a compound of Chemical Formula 1-1 was deposited with a thickness of 10 nm on the emission layer. Then, as an electron transfer layer, Alq was deposited with a thickness of 15 nm on the hole blocking layer. Next, as a cathode, lithium fluoride was deposited with a thickness of 0.5 nm and then aluminum was deposited with a thickness of 150 nm such that an organic light emitting element was manufactured.

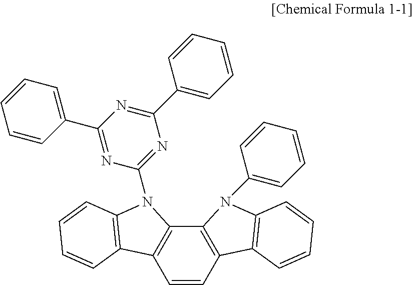 [SMILES: c1ccc(-c2nc(-c3ccccc3)nc(-n3c4ccccc4c4ccc5c6ccccc6n(-c6ccccc6)c5c43)n2)cc1]

With respect to the manufactured organic light emitting element, element performance (i.e., current efficiency, Cd/A) is measured when driving with a current density of 10 mA/cm², and time (i.e., life span) until luminance is decreased to 80% from initial luminance at a current density of 50 mA/cm² was respectively measured.

The host compound of the emission layer was changed to the compounds of Chemical Formula 2-1 to Chemical Formula 2-8, respectively, and a compound of the electron blocking layer was changed to the compounds of Chemical Formula 1-1 to Chemical Formula 1-7, respectively, and then element performance and life span were measured in the same conditions.

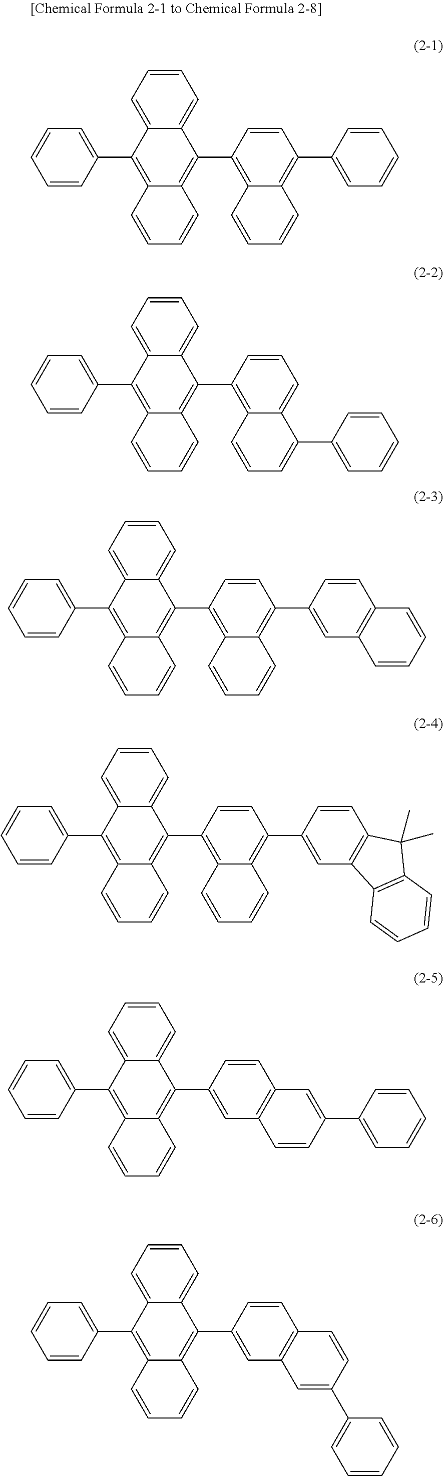

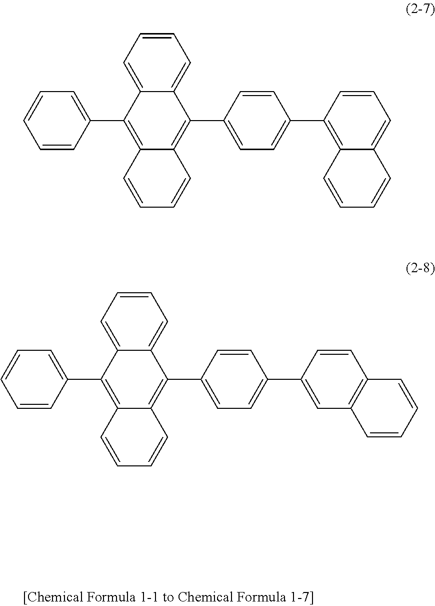

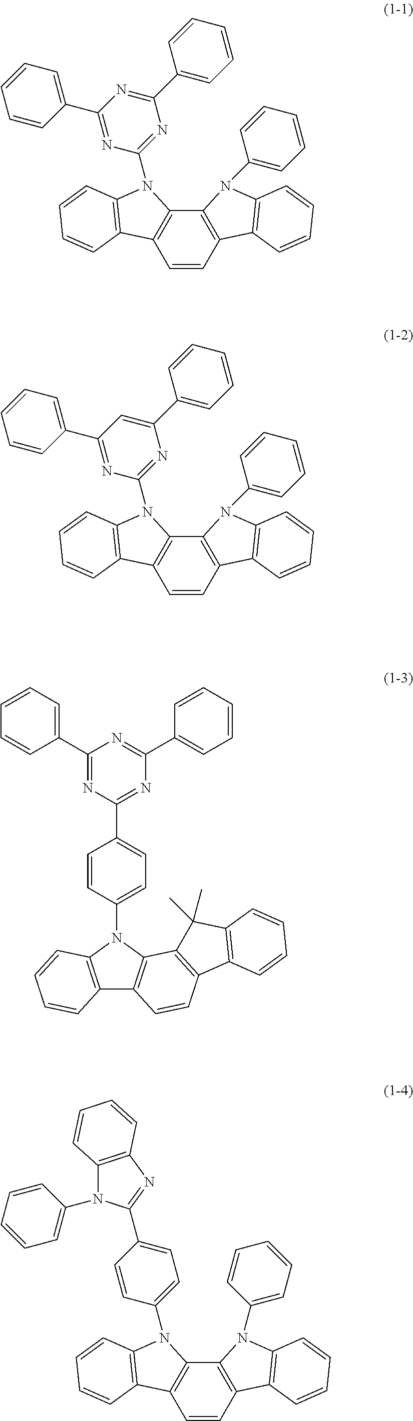 [SMILES: c1ccc(-c2nc(-c3ccccc3)nc(-n3c4ccccc4c4ccc5c6ccccc6n(-c6ccccc6)c5c43)n2)cc1 ; c1ccc(-c2cc(-c3ccccc3)nc(-n3c4ccccc4c4ccc5c6ccccc6n(-c6ccccc6)c5c43)n2)cc1 ; CC1(C)c2ccccc2-c2ccc3c4ccccc4n(-c4ccc(-c5nc(-c6ccccc6)nc(-c6ccccc6)n5)cc4)c3c21 ; c1ccc(-n2c(-c3ccc(-n4c5ccccc5c5ccc6c7ccccc7n(-c7ccccc7)c6c54)cc3)nc3ccccc32)cc1]

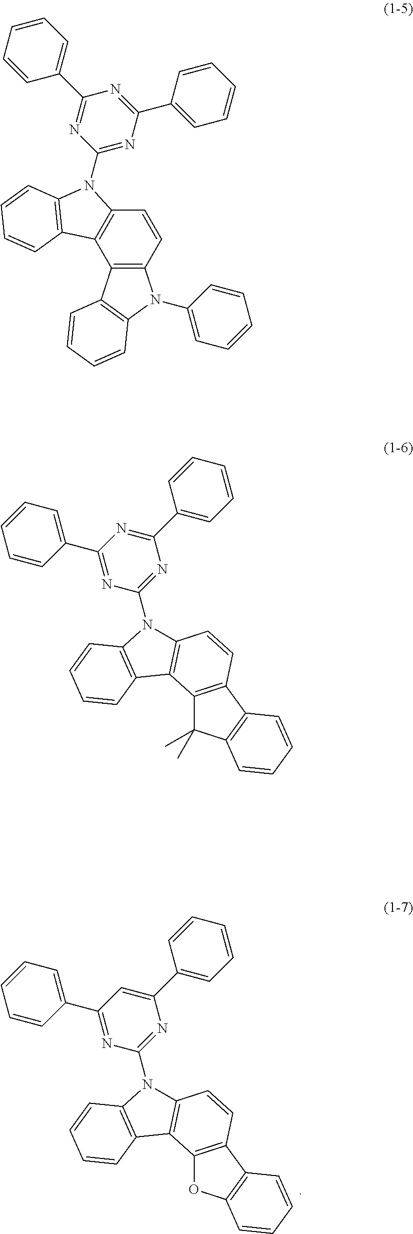 [SMILES: c1ccc(-c2nc(-c3ccccc3)nc(-n3c4ccccc4c4c5c6ccccc6n(-c6ccccc6)c5ccc43)n2)cc1 ; CC1(C)c2ccccc2-c2ccc3c(c21)c1ccccc1n3-c1nc(-c2ccccc2)nc(-c2ccccc2)n1 ; c1ccc(-c2cc(-c3ccccc3)nc(-n3c4ccccc4c4c5oc6ccccc6c5ccc43)n2)cc1 ; "."]

In addition, as Comparative Examples, an organic light emitting element was manufactured with the same conditions as of the above-described organic light emitting element of Example 1, except that a host compound was changed to compounds of Chemical Formula 6 to Chemical Formula 8.

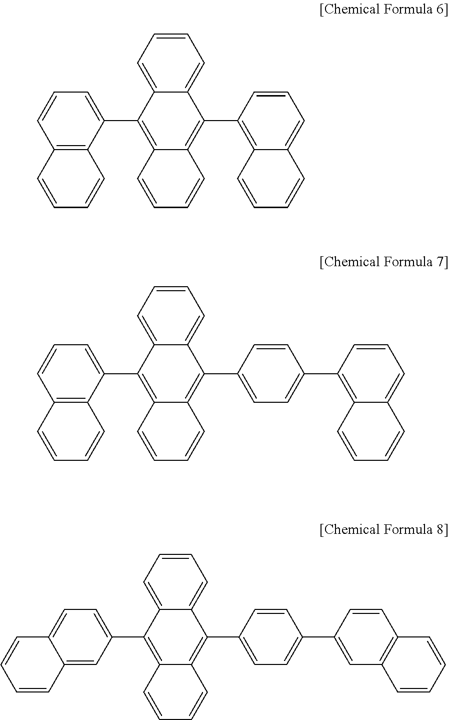

Table 1 shows measurement results.

TABLE 1

| | | Hole | Electron | | Life |
|---|---|---|---|---|---|
| | | blocking | transfer | Efficiency | span |
| Example | Host | layer | layer | (cd/A) | (h) |
| Example 1-1 | Chemical | Chemical | Alq | 5.6 | 120 |
| | Formula 2-1 | Formula 1-1 | | | |
| Example -2 | Chemical | Chemical | Alq | 5.5 | 130 |
| | Formula 2-1 | Formula 1-2 | | | |
| Example 1-3 | Chemical | Chemical | Alq | 5.4 | 140 |
| | Formula 2-1 | Formula 1-3 | | | |
| Example 1-4 | Chemical | Chemical | Alq | 5.5 | 120 |
| | Formula 2-1 | Formula 1-4 | | | |
| Example 1-5 | Chemical | Chemical | Alq | 5.3 | 120 |
| | Formula 2-1 | Formula 1-5 | | | |
| Example 1-6 | Chemical | Chemical | Alq | 5.5 | 110 |
| | Formula 2-1 | Formula 1-6 | | | |
| Example 1-7 | Chemical | Chemical | Alq | 5.3 | 130 |
| | Formula 2-1 | Formula 1-7 | | | |
| Example 1-8 | Chemical | Chemical | Alq | 5.5 | 120 |
| | Formula 2-2 | Formula 1-1 | | | |
| Example 1-9 | Chemical | Chemical | Alq | 5.6 | 120 |
| | Formula 2-3 | Formula 1-1 | | | |
| Example 1-10 | Chemical | Chemical | Alq | 5.5 | 110 |
| | Formula 2-4 | Formula 1-1 | | | |
| Example 1-11 | Chemical | Chemical | Alq | 5.5 | 120 |
| | Formula 2-5 | Formula 1-1 | | | |
| Example 1-12 | Chemical | Chemical | Alq | 5.5 | 130 |
| | Formula 2-6 | Formula 1-1 | | | |
| Example 1-13 | Chemical | Chemical | Alq | 5.4 | 140 |
| | Formula 2-7 | Formula 1-1 | | | |
| Example 1-14 | Chemical | Chemical | Alq | 5.3 | 130 |
| | Formula 2-8 | Formula 1-1 | | | |
| Example 1-15 | Chemical | Chemical | Alq | 5.4 | 130 |
| | Formula 2-2 | Formula 1-3 | | | |
| Example 1-16 | Chemical | Chemical | Alq | 5.5 | 120 |
| | Formula 2-4 | Formula 1-3 | | | |
| Example 1-17 | Chemical | Chemical | Alq | 5.4 | 110 |
| | Formula 2-5 | Formula 1-3 | | | |
| Example 1-18 | Chemical | Chemical | Alq | 5.4 | 120 |
| | Formula 2-7 | Formula 1-3 | | | |
| Example 1-19 | Chemical | Chemical | Alq | 5.5 | 120 |
| | Formula 2-2 | Formula 1-4 | | | |
| Example 1-20 | Chemical | Chemical | Alq | 5.4 | 120 |
| | Formula 2-4 | Formula 1-4 | | | |
| Example 1-21 | Chemical | Chemical | Alq | 5.5 | 130 |
| | Formula 2-5 | Formula 1-4 | | | |
| Example 1-22 | Chemical | Chemical | Alq | 5.3 | 100 |
| | Formula 2-7 | Formula 1-4 | | | |
| Example 1-23 | Chemical | Chemical | Alq | 5.4 | 110 |
| | Formula 2-2 | Formula 1-6 | | | |
| Example 1-24 | Chemical | Chemical | Alq | 5.5 | 110 |
| | Formula 2-4 | Formula 1-6 | | | |
| Example 1-25 | Chemical | Chemical | Alq | 5.4 | 120 |
| | Formula 2-5 | Formula 1-6 | | | |
| Example 1-26 | Chemical | Chemical | Alq | 5.3 | 110 |
| | Formula 2-7 | Formula 1-6 | | | |
| Comparative | Chemical | Chemical | Alq | 4.4 | 50 |
| Example 1 | Formula 6 | Formula 1-1 | | | |
| Comparative | Chemical | Chemical | Alq | 5.0 | 100 |
| Example 2 | Formula 7 | Formula 1-1 | | | |
| Comparative | Chemical | Chemical | Alq | 4.9 | 90 |
| Example 3 | Formula 8 | Formula 1-1 | | | |

### Example 2

An organic light emitting element is manufactured with the same conditions of Example 1, except that 50 wt % of Liq was simultaneously deposited as a doping material to a BPhen compound to form an electron transfer layer. Efficiency and life span of the manufactured organic light emitting element are measured with the same conditions of Example 1, and measurement results are shown in Table 2.

TABLE 2

| | | Hole blocking | Electron transfer | | |
|---|---|---|---|---|---|
| Example | Host | layer | layer | Efficiency (cd/A) | Life span (h) |
| Example 2-1 | Chemical | Chemical | BPhen:Liq | 5.4 | 130 |
| | Formula 2-1 | Formula 1-1 | | | |
| Example 2-2 | Chemical | Chemical | BPhen:Liq | 5.4 | 140 |
| | Formula 2-1 | Formula 1-2 | | | |
| Example 2-3 | Chemical | Chemical | BPhen:Liq | 5.3 | 150 |
| | Formula 2-1 | Formula 1-3 | | | |
| Example 2-4 | Chemical | Chemical | BPhen:Liq | 5.4 | 140 |
| | Formula 2-1 | Formula 1-4 | | | |
| Example 2-5 | Chemical | Chemical | BPhen:Liq | 5.2 | 130 |
| | Formula 2-1 | Formula 1-5 | | | |
| Example 2-6 | Chemical | Chemical | BPhen:Liq | 5.3 | 140 |
| | Formula 2-1 | Formula 1-6 | | | |
| Example 2-7 | Chemical | Chemical | BPhen:Liq | 5.4 | 130 |
| | Formula 2-1 | Formula 1-7 | | | |
| Example 2-8 | Chemical | Chemical | BPhen:Liq | 5.4 | 130 |
| | Formula 2-2 | Formula 1-1 | | | |
| Example 2-9 | Chemical | Chemical | BPhen:Liq | 5.4 | 140 |
| | Formula 2-3 | Formula 1-1 | | | |
| Example 2-10 | Chemical | Chemical | BPhen:Liq | 5.5 | 130 |
| | Formula 2-4 | Formula 1-1 | | | |
| Example 2-11 | Chemical | Chemical | BPhen:Liq | 5.4 | 130 |
| | Formula 2-5 | Formula 1-1 | | | |
| Example 2-12 | Chemical | Chemical | BPhen:Liq | 5.4 | 130 |
| | Formula 2-6 | Formula 1-1 | | | |
| Example 2-13 | Chemical | Chemical | BPhen:Liq | 5.3 | 140 |
| | Formula 2-7 | Formula 1-1 | | | |
| Example 2-14 | Chemical | Chemical | BPhen:Liq | 5.3 | 140 |
| | Formula 2-8 | Formula 1-1 | | | |
| Example 2-15 | Chemical | Chemical | BPhen:Liq | 5.3 | 150 |
| | Formula 2-2 | Formula 1-3 | | | |
| Example 2-16 | Chemical | Chemical | BPhen:Liq | 5.4 | 140 |
| | Formula 2-4 | Formula 1-3 | | | |
| Example 2-17 | Chemical | Chemical | BPhen:Liq | 5.4 | 140 |
| | Formula 2-5 | Formula 1-3 | | | |
| Example 2-18 | Chemical | Chemical | BPhen:Liq | 5.3 | 130 |
| | Formula 2-7 | Formula 1-3 | | | |
| Example 2-19 | Chemical | Chemical | BPhen:Liq | 5.5 | 140 |
| | Formula 2-2 | Formula 1-4 | | | |
| Example 2-20 | Chemical | Chemical | BPhen:Liq | 5.4 | 130 |
| | Formula 2-4 | Formula 1-4 | | | |
| Example 2-21 | Chemical | Chemical | BPhen:Liq | 5.4 | 130 |
| | Formula 2-5 | Formula 1-4 | | | |
| Example 2-22 | Chemical | Chemical | BPhen:Liq | 5.3 | 150 |
| | Formula 2-7 | Formula 1-4 | | | |
| Example 2-23 | Chemical | Chemical | BPhen:Liq | 5.3 | 140 |
| | Formula 2-2 | Formula 1-6 | | | |
| Example 2-24 | Chemical | Chemical | BPhen:Liq | 5.3 | 130 |
| | Formula 2-4 | Formula 1-6 | | | |
| Example 2-25 | Chemical | Chemical | BPhen:Liq | 5.2 | 140 |
| | Formula 2-5 | Formula 1-6 | | | |
| Example 2-26 | Chemical | Chemical | BPhen:Liq | 5.3 | 130 |
| | Formula 2-7 | Formula 1-6 | | | |
| Comparative | Chemical | Chemical | BPhen:Liq | 4.3 | 60 |
| Example 4 | Formula 6 | Formula 1-1 | | | |
| Comparative | Chemical | Chemical | BPhen:Liq | 4.8 | 100 |
| Example 5 | Formula 7 | Formula 1-1 | | | |
| Comparative | Chemical | Chemical | BPhen:Liq | 4.7 | 110 |
| Example 6 | Formula 8 | Formula 1-1 | | | |

As shown in Table 2, it may be seen that when the compounds of Chemical Formula 1-1 to Chemical Formula 1-7 and the compounds of Chemical Formula 2 were included in a hole blocking layer and a host material, respectively, efficiency and life span were significantly improved. Referring to Table 2, even though the compounds of Chemical Formula 1-1 to Chemical Formula 1-7 were used in the hole blocking layer, efficiency and life span were improved compared to a case that the compounds of Chemical Formula 6 to Chemical Formula 8 are used as a host as in the Comparative Examples.

For example, efficiency and life span of the organic light emitting element may be improved by using a phenyl-substituted anthracene-based compound as a host and a carbazole-based compound as an electron blocking layer.

It may be seen in Table 1 and Table 2 that when the organic light emitting element is made of the above-stated combinations, high efficiency and long life span may be acquired, regardless of the type of electron transfer layer material.

By way of summation and review, some organic light emitting devices may have a high driving voltage, high light emission brightness, low luminance and light emission efficiency, and a short life span.

The embodiments may provide an organic light emitting element having high efficiency and a long life span.

As described, the efficiency and life span of the organic light emitting element may be improved by using or including a carbazole-based or carbazole-containing compound as or in a hole blocking layer of the organic light emitting element, and a phenyl-substituted anthracene-based or containing compound as or in an emission layer of the organic light emitting element.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

<Description of symbols>

| | | | |
|---|---|---|---|
| 10: | anode | 20: | cathode |
| 30: | hole transfer layer | 40: | electron transfer layer |
| 50: | electron blocking layer | 60: | emission layer |

What is claimed is:

1. An organic light emitting element, comprising:
a first compound represented by one of Chemical Formula 1-A to Chemical Formula 1-G, and
a second compound represented by Chemical Formula 2: 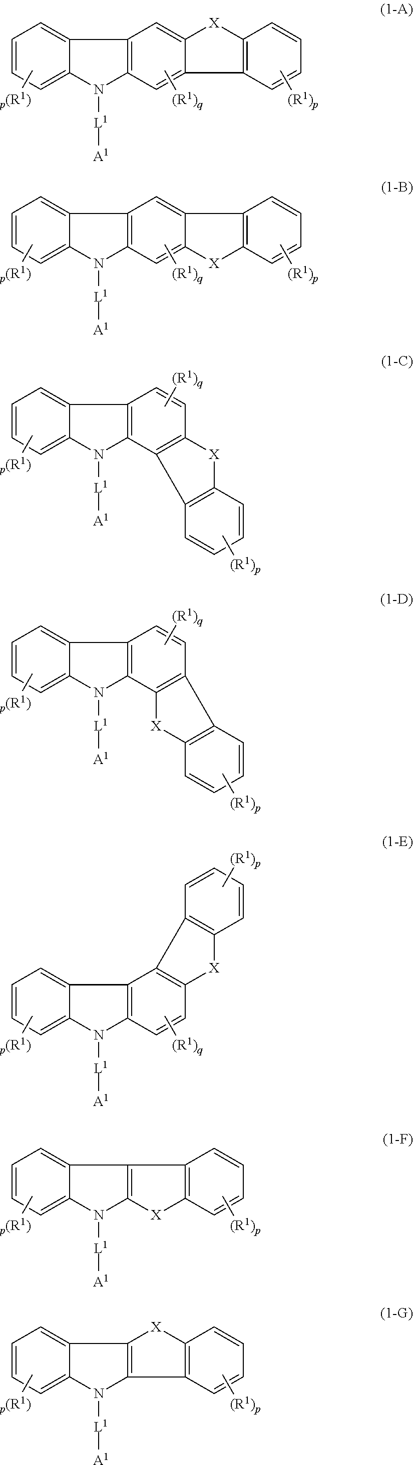
wherein, in Chemical Formula 1-A to Chemical Formula 1-G,
A¹ is a substituted or unsubstituted C6 to C30 aromatic hydrocarbon group or a substituted or unsubstituted ring-type C6 to C30 condensed aromatic heterocyclic group,
L¹ is a single bond, a substituted or unsubstituted C6 to C30 aromatic hydrocarbon group, a substituted or unsubstituted C6 to C30 condensed aromatic hydrocarbon group, a substituted or unsubstituted C2 to C30 aromatic heterocyclic group, or a substituted or unsubstituted C2 to C30 condensed aromatic heterocyclic group,
X is S, O, N—R¹, or C(R¹)₂,
each R¹ is independently hydrogen, fluorine, a cyano group, a substituted or unsubstituted C1 to C20 alkyl group, a substituted or unsubstituted C1 to C20 alkoxy group, a substituted or unsubstituted C1 to C20 haloalkyl group, a substituted or unsubstituted C1 to C20 haloalkoxy group, a substituted or unsubstituted C1 to C10 alkylsilyl group, a substituted or unsubstituted C6 to C30 arylsilyl group, a substituted or unsubstituted C6 to C30 aromatic hydrocarbon group, a substituted or unsubstituted C6 to C30 condensed aromatic hydrocarbon group, a substituted or unsubstituted C2 to C30 aromatic heterocyclic group, or a substituted or unsubstituted C2 to C30 condensed aromatic heterocyclic group,
p is an integer of 1 to 4,
q is an integer of 1 to 2, 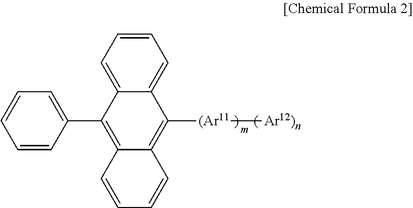
wherein, in Chemical Formula 2,
each Ar¹¹ is independently a substituted or unsubstituted C5 to C30 arylene group or a substituted or unsubstituted C5 to C30 heteroarylene group,
m is an integer of 0 to 3, such that when m is 0, Ar¹¹ is a single bond,
each Ar¹² is independently a substituted or unsubstituted C5 to C30 aryl group or a substituted or unsubstituted C5 to C30 heteroaryl group, and
n is an integer of 1 to 3.

2. The organic light emitting element as claimed in claim 1, wherein:
the organic light emitting element includes:
an anode and a cathode that face each other;
an emission layer between the anode and the cathode;
a hole transfer layer between the anode and the emission layer;
an electron transfer layer between the cathode and the emission layer; and
a hole blocking layer between the electron transfer layer and the emission layer,
the hole blocking layer includes the first compound, and
the emission layer includes the second compound.

3. The organic light emitting element as claimed in claim 1, wherein Ar¹¹ of the second compound includes a substituted or unsubstituted phenylene group or a substituted or unsubstituted naphthylene group.

4. The organic light emitting element as claimed in claim 1, wherein the first compound is represented by one of the following Chemical Formula 1-1 to Chemical Formula 1-7:

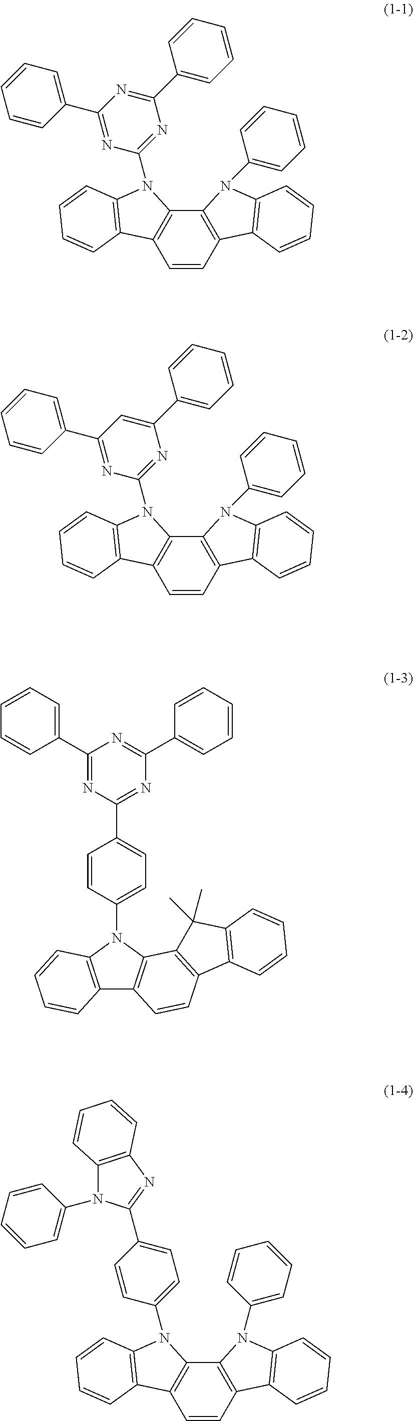 [SMILES: c1ccc(-c2nc(-c3ccccc3)nc(-n3c4ccccc4c4ccc5c6ccccc6n(-c6ccccc6)c5c43)n2)cc1 ; c1ccc(-c2cc(-c3ccccc3)nc(-n3c4ccccc4c4ccc5c6ccccc6n(-c6ccccc6)c5c43)n2)cc1 ; CC1(C)c2ccccc2-c2ccc3c4ccccc4n(-c4ccc(-c5nc(-c6ccccc6)nc(-c6ccccc6)n5)cc4)c3c21 ; c1ccc(-n2c(-c3ccc(-n4c5ccccc5c5ccc6c7ccccc7n(-c7ccccc7)c6c54)cc3)nc3ccccc32)cc1]

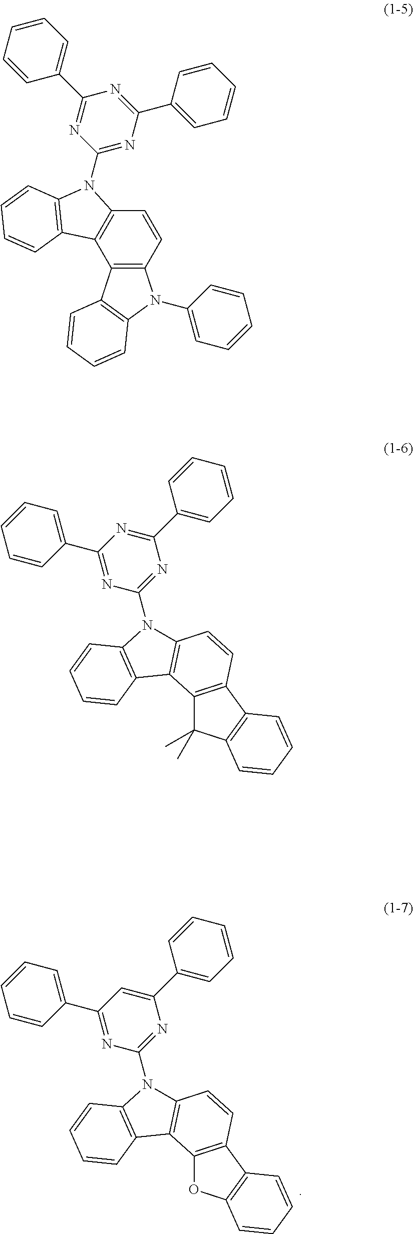 [SMILES: c1ccc(-c2nc(-c3ccccc3)nc(-n3c4ccccc4c4c5c6ccccc6n(-c6ccccc6)c5ccc43)n2)cc1 ; CC1(C)c2ccccc2-c2ccc3c(c21)c1ccccc1n3-c1nc(-c2ccccc2)nc(-c2ccccc2)n1 ; c1ccc(-c2cc(-c3ccccc3)nc(-n3c4ccccc4c4c5oc6ccccc6c5ccc43)n2)cc1 ; "."]

5. The organic light emitting element as claimed in claim 1, wherein the second compound is represented by one of the following Chemical Formula 2-1 to Chemical Formula 2-8:

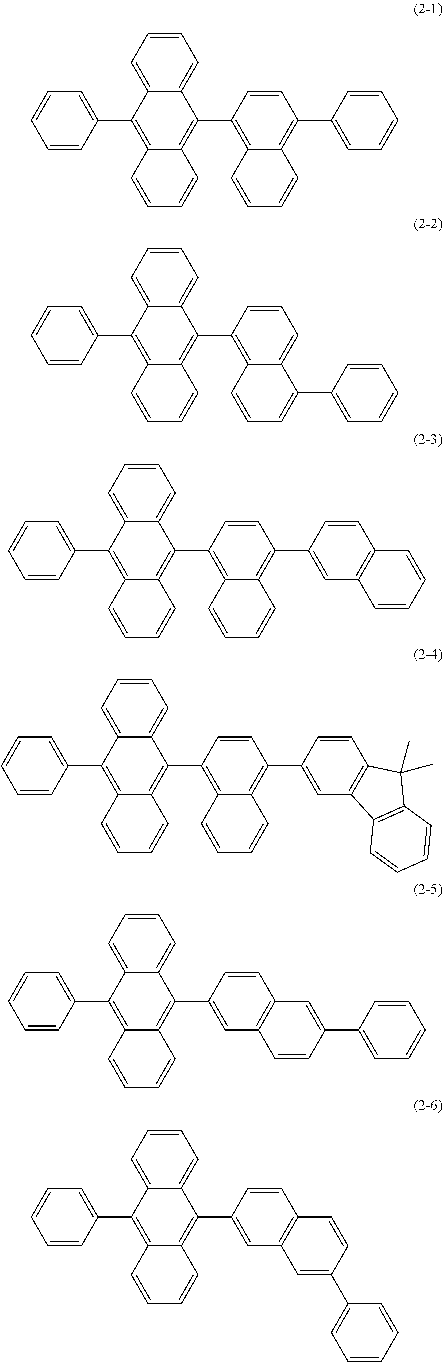

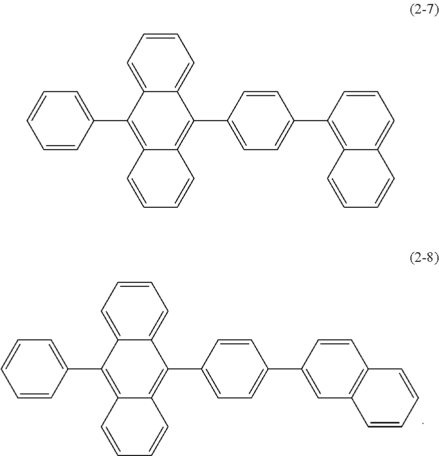

6. The organic light emitting element as claimed in claim 2, wherein the electron transfer layer includes a metal or a metal complex.

7. The organic light emitting element as claimed in claim 2, wherein the hole blocking layer has a thickness of about 1 nm to about 100 nm.

8. An organic light emitting display, comprising:
a substrate;
gate lines on the substrate;
data lines and a driving voltage line crossing the gate lines;
a switching thin film transistor connected with the gate line and the data line;
a driving thin film transistor connected with the switching thin film transistor and the driving voltage line; and
an organic light emitting element connected with the driving thin film transistor,
wherein the organic light emitting element includes:
a first compound represented by one of Chemical Formula 1-A to Chemical Formula 1-G, and
a second compound represented by Chemical Formula 2: 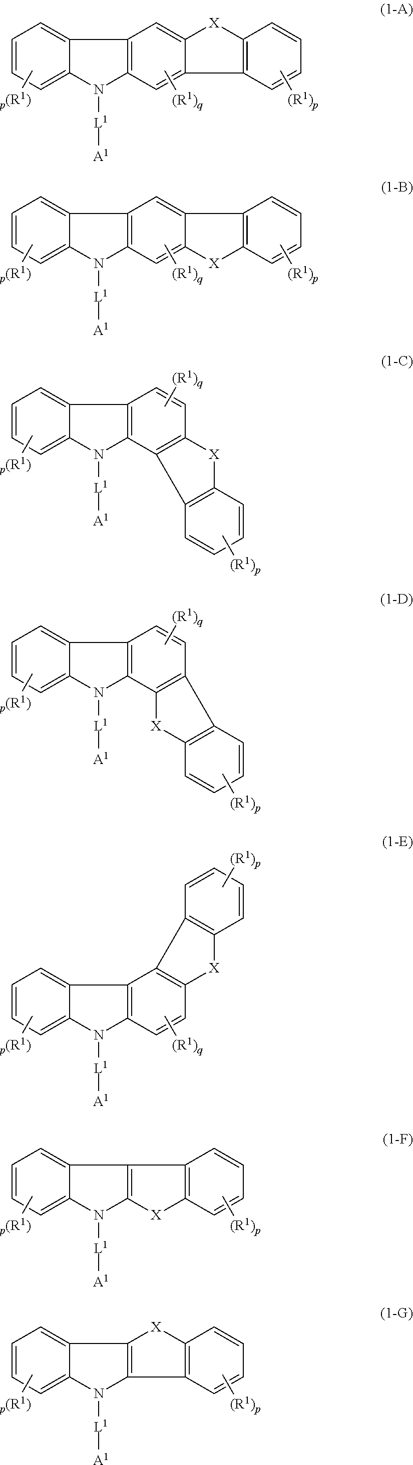
wherein, in Chemical Formula 1-A to Chemical Formula 1-G,
A¹ is a substituted or unsubstituted C6 to C30 aromatic hydrocarbon group or a substituted or unsubstituted C6 to C30 condensed aromatic heterocyclic group,
L¹ is a single bond, a substituted or unsubstituted C6 to C30 aromatic hydrocarbon group, a substituted or unsubstituted C6 to C30 condensed aromatic hydrocarbon group, a substituted or unsubstituted C2 to C30 aromatic heterocyclic group, or a substituted or unsubstituted C2 to C30 condensed aromatic heterocyclic group,
X is S, O, N—R¹, or C(R¹)₂,
each R¹ is independently, hydrogen, fluorine, a cyano group, a substituted or unsubstituted C1 to C20 alkyl group, a substituted or unsubstituted C1 to C20 alkoxy group, a substituted or unsubstituted C1 to C20 haloalkyl group, a substituted or unsubstituted C1 to C20 haloalkoxy group, a substituted or unsubstituted C1 to C10 alkylsilyl group, a substituted or unsubstituted C6 to C30 arylsilyl group, a substituted or unsubstituted C6 to C30 aromatic hydrocarbon group, a substituted or unsubstituted C6 to C30 condensed aromatic hydrocarbon group, a substituted or unsubstituted C2 to C30 aromatic heterocyclic group, or a substituted or unsubstituted C2 to C30 condensed aromatic heterocyclic group,
p is an integer of 1 to 4,
q is an integer of 1 to 2, 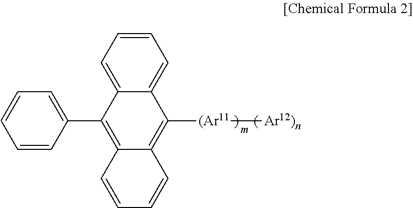
wherein, in Chemical Formula 2,
each Ar¹¹ is independently a substituted or unsubstituted C5 to C30 arylene group or a substituted or unsubstituted C5 to C30 heteroarylene group,
m is an integer of 0 to 3, such that when m is 0, Ar¹¹ is a single bond,
each Ar¹² is independently a substituted or unsubstituted C5 to C30 aryl group or a substituted or unsubstituted C5 to C30 heteroaryl group, and
n is an integer of 1 to 3.

9. The organic light emitting display as claimed in claim 8, wherein:
the organic light emitting element includes:
an anode and a cathode that face each other;
an emission layer between the anode and the cathode;
a hole transfer layer between the anode and the emission layer;
an electron transfer layer between the cathode and the emission layer; and
a hole blocking layer between the electron transfer layer and the emission layer,
the hole blocking layer includes the first compound, and
the emission layer includes the second compound.

10. The organic light emitting display as claimed in claim 8, wherein Ar¹¹ of the second compound includes a substituted or unsubstituted phenylene group or a substituted or unsubstituted naphthalenylene group.

11. The organic light emitting display as claimed in claim 8, wherein the first compound is represented by one of the following Chemical Formula 1-1 to Chemical Formula 1-7:

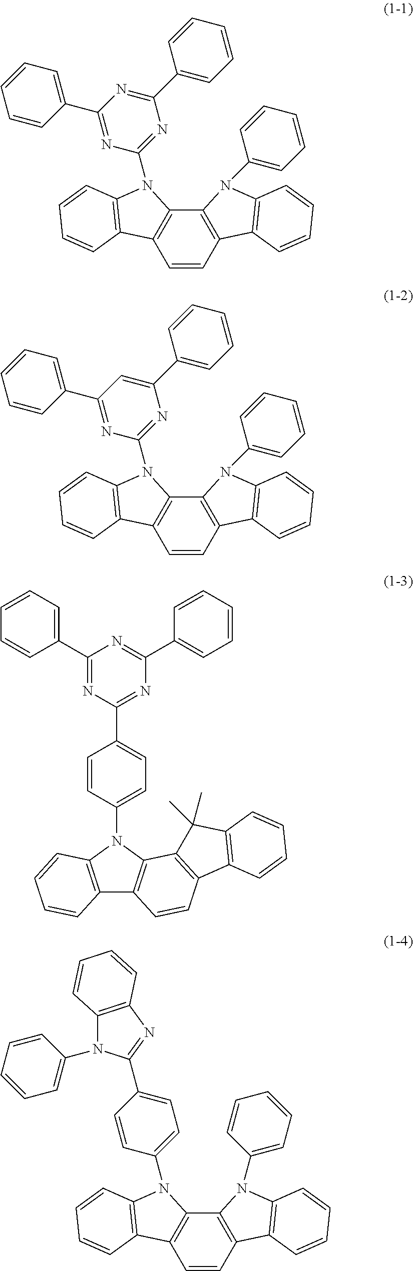

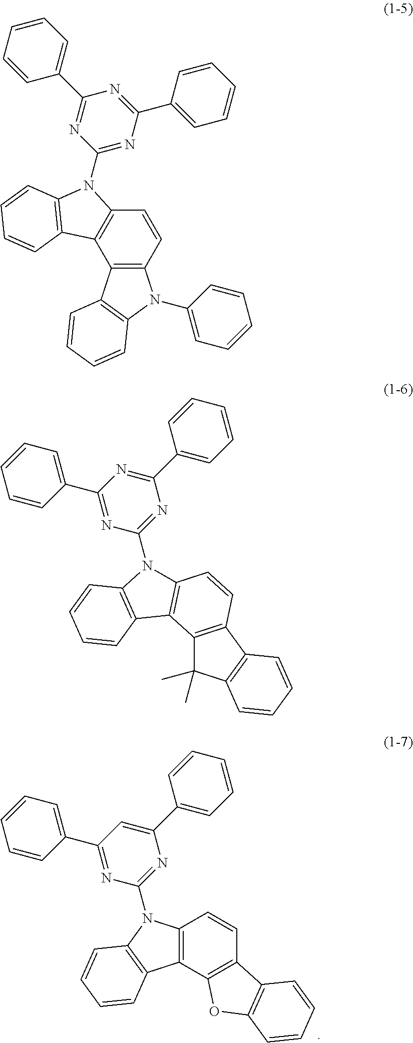 [SMILES: c1ccc(-c2nc(-c3ccccc3)nc(-n3c4ccccc4c4c5c6ccccc6n(-c6ccccc6)c5ccc43)n2)cc1 ; CC1(C)c2ccccc2-c2ccc3c(c21)c1ccccc1n3-c1nc(-c2ccccc2)nc(-c2ccccc2)n1 ; c1ccc(-c2cc(-c3ccccc3)nc(-n3c4ccccc4c4c5oc6ccccc6c5ccc43)n2)cc1]

12. The organic light emitting display as claimed in claim 8, wherein the second compound is represented by one of the following Chemical Formula 2-1 to Chemical Formula 2-8:

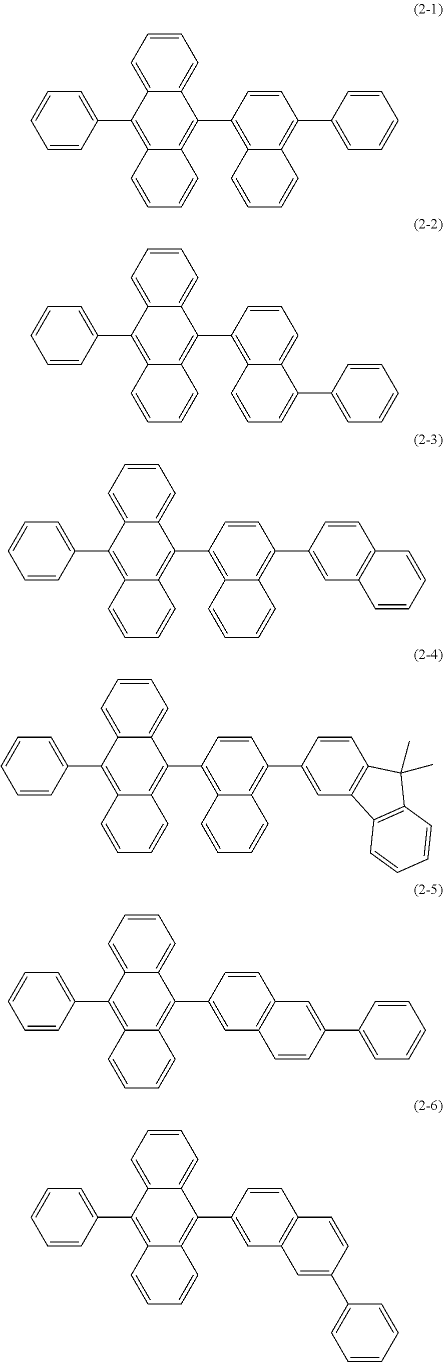

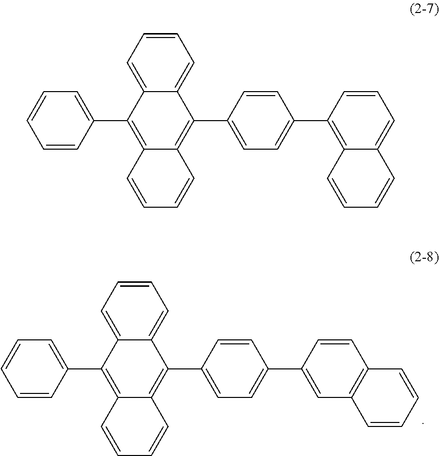

13. The organic light emitting display as claimed in claim 8, wherein the electron transfer layer includes a metal or a metal complex.

14. The organic light emitting display as claimed in claim 8, wherein the hole blocking layer has a thickness of about 1 nm to about 100 nm.
